(19) United States
(12) Patent Application Publication
(10) Pub. No.: US 2015/0072159 A1
(43) Pub. Date: Mar. 12, 2015

(54) CONDUCTIVE FILM AND ORGANIC ELECTROLUMINESCENT ELEMENT

(71) Applicant: Konica Minolta, Inc., Chiyoda-ku, Tokyo (JP)

(72) Inventors: Kazuaki Nakamura, Tokyo (JP); Satomi Kawabe, Tokyo (JP); Takayuki Suzuki, Tokyo (JP)

(21) Appl. No.: 14/391,544

(22) PCT Filed: Mar. 29, 2013
(86) PCT No.: PCT/JP2013/059713

§ 371 Date: Oct. 9, 2014

(30) Foreign Application Priority Data
Apr. 9, 2012 (JP) 2012-088742

(51) Int. Cl. H01B 1/12; H05K 1/02; H01L 51/52; H05K 1/09

(52) U.S. Cl. CPC H01B 1/125; H05K 1/092; H05K 1/0274; H01L 51/5203
USPC 428/461; 174/257

(57) ABSTRACT

Provided is a conductive film with excellent transparency, conductivity, and film strength and in which there is minimal degradation of the transparency, conductivity, and film strength even in a high temperature and high humidity environment. A conductive film is provided with a base material and an organic compound layer that is conductive and is formed on top of the base material. The conductive film is characterized by the organic compound layer including a conductive polymer compound containing a cationic π conjugated system conductive polymer and a polyanion, and a polyolefin copolymer.

### CROSS REFERENCE TO RELATED APPLICATIONS

This is the U.S. national stage of application No. PCT/JP2013/059713, filed on Mar. 29, 2013. Priority under 35 U.S.C. §119(a) and 35 U.S.C. §365(b) is claimed from Japanese Application No. 2012-088742, filed Apr. 9, 2012, the disclosure of which is also incorporated herein by reference.

### FIELD OF THE TECHNOLOGY

The present invention relates to a conductive film suitably used in the field of a liquid crystal display equipment, an organic light emitting element, an inorganic electroluminescent element, a solar battery, an electromagnetic wave shield, an electronic-paper, touch-panel, and so on, and relates to an organic electroluminescent element (so called organic EL element) using said conductive film.

### BACKGROUND OF THE INVENTION

In recent years, various types displays like a liquid crystal, a plasma, an organic electroluminescence, a field emission and so on are developed in accordance with the higher demand of thin TV. For every display which is different from display type, a transparent electrode has become a necessary technological element. Further, for a touch panel, a cell phone, the electronic-paper, the various solar batteries, the various electroluminescent element etc. in addition to TV, the transparent electrode has become the necessary technological element.

An ITO transparent electrode, which is provided by coating Indium-Tin complex oxide (ITO) film on a transparent substrate of glass or transparent plastic film by vacuum deposition or spattering method has been used as the transparent electrode up to now. However, Indium used in ITO is rare metal and not using Indium is desired because of soaring of the price. Further, a larger screen and “role to role” production technology using a flexible substrate in accordance with the higher productivity are desired.

A transparent conductive film with both a surface homogeneity of electric current and high conductivity which is provided by laminating a transparent electrode of conductive polymer etc. on a patterned metal fine wire is developed in recent years for the adaption to a product demanding large surface and low resistance.

However, such an upper structure needs smoothing irregularity of the metal fine wire which can cause leak of an organic electronic device, with the transparent electrode of conductive polymer. The conductive polymer must become thick. But, if conductive polymer becomes thick, the decreased transparency of the transparent electrode becomes a problem because conductive polymer has absorption in the range of visible wave length.

A technology laminating fine wire structure with conductive polymer, a technology using binder resin homogeneously dispersible in the conductive polymer and water solvent on a conductive fiber (for example, see Japanese Unexamined Patent Application Publication No. 2010-244746.) and a technology putting high conductivity, transparency and smoothness into practice under the environment of high temperature and high humidity are disclosed in order that conductivity and transparency stand side by side.

Further, “role to role” production technology using the flexible substrate uses widely polymer film in the view of handling, but drying at low temperature and for short time is desired. Smaller amount of water soluble polymer in the material which is used to provide the transparent electrode, is demanded to reduce drying load, and as conductive material with small amount of water soluble polymer, conductive composition using polyester emulsion (for example, see Japanese Unexamined Patent Application Publication No. 2009-230885.) is known. Further, as technology to reduce drying load by using particles, conductive composition composed of resin particles including polyolefin resin particle (for example, see Japanese Unexamined Patent Application Publication No. 2011-116860) is known.

### PRIOR ART DOCUMENT

### Patent Document

Patent document 1: JP2010-244746 (A)

Patent document 2: JP2009-230885 (A)

Patent document 3: JP2011-116860 (A)

### SUMMARY OF THE INVENTION

### Problems to be Solved by the Invention

However, technology written in Japanese Unexamined Patent Application Publication No. 2010-244746 doesn't show enough feature under the environment at high temperature and high humidity. There was a problem that achievement of conductivity, transparency and smoothness was difficult. Further, materials written in Japanese Unexamined Patent Application Publications No. 2009-230885 and No. 2011-116860 don't have enough drying property, so a volatile material like water etc. diffuses between layers in the environmental test. The electrode and the organic EL element were influenced badly and desirable preservation feature was not able to obtain. That was a problem, too. Further, not enough mutual solubility or influence of coarse particles in organic particles and inorganic particles could cause feature of conductive film's Hays level and surface roughness not to be obtained. The feature of organic EL element could be worsened because desirable feature of the film cannot be obtained. That was a problem, too.

The present invention was conceived after considering the subjects described in the above. The present invention is to provide a transparent electrode excellent in the transparency, electroconductivity and strength of electrode, and less likely to degrade the transparency, electroconductivity and strength of electrode even under high-temperature, high-humidity environments. The present invention is also to provide an organic EL device using the transparent electrode, excellent in emission uniformity, less causative of degradation in the emission uniformity even under high temperature, high humidity environments, and have a long service life of emission.

### Means to Solve the Problems

The above problems of the present invention will be solved by the following means.

(1) A conductive film comprising:
a substrate and
a conductive organic compound layer formed on the substrate,

wherein said organic compound layer includes:
cationic π conjugated conductive polymer,
conductive polymer compound having poly-anion, and
polyolefin copolymer.

(2) The conductive film according to said (1), wherein said polyolefin copolymer is a copolymer of ethylene and (meth)acrylic acid.

(3) The conductive film according said (1) or (2), wherein said organic compound layer includes fine particles.

(4) The conductive film according to one of said (1)˜(3), wherein on the said substrate, formed
A first conductive layer composed of patterned metal material
A second conductive layer composed of said organic compound layer connected electrically to said the first conductive layer.

(5) An organic electroluminescent element, equipped with the conductive film according to one of (1)˜(4) as an electrode.

### Advantageous Effect of the Invention

The present invention provides a conductive film of good transparency, conductivity and strength as well as little degradation of transparency, conductivity and strength under the environment of high temperature and high humidity. The present invention also provides an organic EL element of good emission homogeneity, little degradation of emission homogeneity under the environment of high temperature and high humidity and good emission life-time, using said conductive film.

### BRIEF DESCRIPTION OF THE DRAWINGS

FIG. 1A and FIG. 1B are schematic showing an example of conductive film of the embodiment of the present invention. FIG. 1A is a top view. FIG. 1B is a cross section of FIG. 1A cut by X arrow.

FIG. 2 is a cross section showing an example of a touch panel.

FIG. 3 shows Table 1 from the specification.

FIG. 4 shows Table 2 from the specification.

FIG. 5 shows Table 3 from the specification.

### DETAILED DESCRIPTION OF THE INVENTION

### Embodiment of the Invention

A coating solution forming conductive layer on the substrate of the conductive film up to now, which is composition including water dispersible conductive polymer like 3,4-polyethylene-dioxy-thiophen/polystyrene sulfonate (PEDOT/PSS) etc. and binder resin, is developed in order to achieve both the excellent conductivity and the excellent transparency.

Further, as binder resin, hydrophilic binder resin has been researched in the view of mutual solubility with a water dispersible conductive polymer. But the demand on the flexibility of the substrate becomes higher, when resin film of polyethylene terephthalate etc. is used as the substrate, the drying temperature must be lower comparing with the glass substrate in the view of avoiding film deformation. Further, the binder resin having hydroxyl radical which is known as mutually soluble with PEDOT/PSS, cross-links between polymer chains after dehydration of hydroxyl radical under acid condition. If drying temperature is low, bad cross-linkage occurs, as a result, not only cross-linkage proceeds and the dehydrated water generates, but also the feature of the conductive film and the element using the conductive film could drop in quality because of the influence of the remaining water in the film. It was necessary to reduce the interaction between the main structure of the binder resin and water in the prior conductive film to solve this problem.

A polymer emulsion is known as the binder resin having the low interaction with the solvent of water etc. Not only a polyester emulsion, an acryl emulsion, a polyurethane emulsion etc. of polymer emulsions have a lot of ester radicals and urethane radicals in the main chains and side chains, but also hydrophilic radicals of sulfonic acids, carboxylic acids, hydroxyl radicals, ammonium etc. are existing in the chains to make the dispersibility to the solvent higher. If a lot of the hydrophilic sites are existing in the polymer, it is not possible to volatile the water by drying at low temperature and in a short time, and the problem was that feature of the conductive film and the organic EL element using the conductive film could drop in quality. That is, it is necessary to increase hydrophobic property of the main binder resin or to reduce the amount of the binder resin to increase the drying property of the conductive film.

The inventors of the present invention have researched to improve these phenomena. As a result, the inventors have found that a polyolefin copolymer, especially copolymer of ethylene and (meth)acrylic acid is used as the binder resin to be mixed with the conductive polymer or fine particles are added additionally.

That is, the problem of the present invention has been solved by using the polyolefin copolymer, especially copolymer of ethylene and (meth)acrylic acid as the binder resin to be mixed with the conductive polymer or by adding fine particles additionally. And the present invention has been achieved.

The present invention uses the polyolefin copolymer, especially copolymer of ethylene and (meth)acrylic acid as the binder resin to be mixed with the conductive polymer or adds fine particles additionally. By doing so, both the excellent transparency and the excellent conductivity of the conductive film can be achieved, and also the conductive film can be made as a strong film, and shows its high conductivity, transparency and good film strength even after the environmental test under the environment of high temperature and high humidity. By reducing the hydration water generated from the binder resin, it was found that the conductive film of good stability and the organic EL element using the conductive film of long life-time can be obtained.

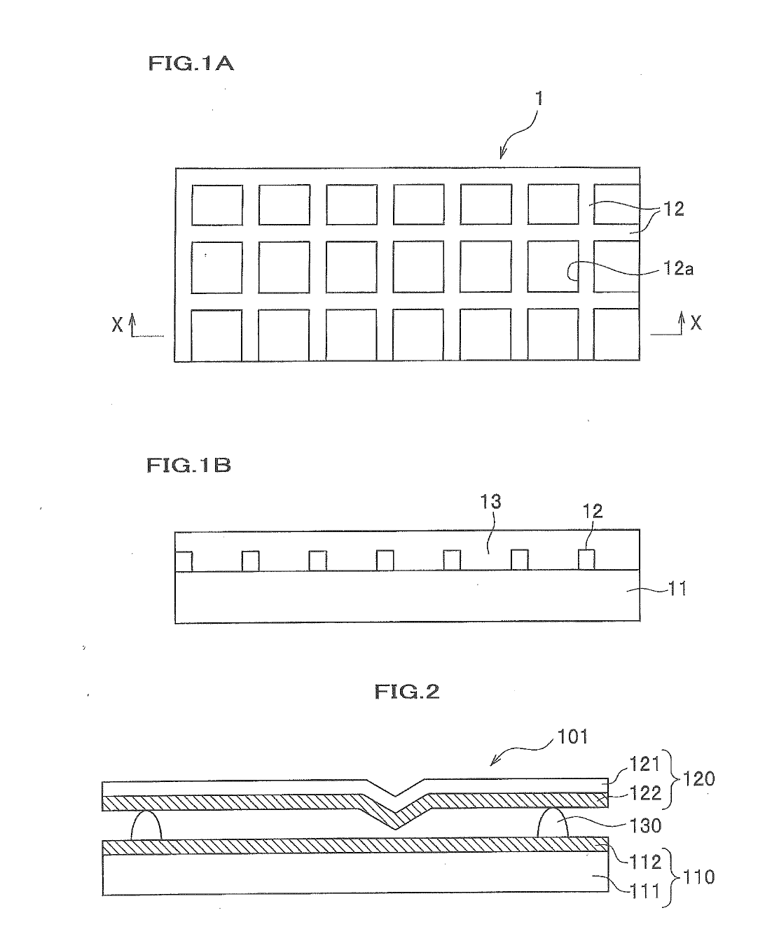

The explanation on the embodiments of the present invention will be made in the following part. FIG. 1A and FIG. 1B are schematic showing an example of conductive film of the embodiment of the present invention. FIG. 1A is a top view. FIG. 1B is a cross section of FIG. 1A cut by X arrow.

As shown in FIG. 1, the conductive film 1 of the embodiment of the present invention is comprised of the substrate 11, the first conductive layer 12, the second conductive layer 13. The first conductive layer 12 is comprised of patterned metal material. The second conductive layer 13 is comprised of the conductive polymer and the polyolefin copolymer. The second conductive layer 13 is an organic compound layer with conductivity as well, which is electrically connected to the first conductive layer 12. The feature of the present invention is that the second conductive layer 13 includes the polyolefin copolymer. Further, the first conductive layer 12 is optional.

### The Polyolefin Copolymer

The polyolefin copolymer is dispersible in an aqueous solvent. Dispersible in an aqueous solvent means dispersion of colloidal particles made of the binder resin without condensation in the aqueous solvent. A size of the colloidal particles (mean diameter) is generally 0.001˜1 μm (1˜1000 nm). The size of a self dispersible polymer including dissociable radicals before dispersion treatment is, as well as colloidal particles of the conductive polymer, preferably 1˜500 nm, more preferably 5˜300 nm, further preferably 5˜100 nm. If the size of the colloidal particles of the polyolefin copolymer is smaller than 500 nm, the Hays level and smoothness (surface roughness (Ra)) of the second conductive layer (conductive layer) 13 formed by coating to the substrate 11 with the dispersion liquid improve. Further, if the size of the colloidal particles of the polyolefin copolymer is bigger than 1 nm, the generation of condensation of the each particle is reduced and the dispersibility of the dispersion liquid is improved, as a result, the Hays level and smoothness (surface roughness (Ra)) of the second conductive layer (conductive layer) 13 is improved. The size of the colloidal particles is preferably 30˜300 nm to increase the smoothness of the film forming, more preferably 5˜100 nm. Such sizes of the colloidal particles are measured by the light scattering photometer.

Further, said aqueous solvent can be not only water (including distilled water and de-ionized water), but also acid, alkali, solution of a salt etc., organic solvent including water or hydrophilic organic solvent. The aqueous solvent is pure water (including distilled water and de-ionized water), alcohol of methanol, ethanol etc. or mixed solvent of the water and the alcohol.

The polyolefin copolymer of the present invention is preferably transparent. The polyolefin copolymer is not limited, if the material can form film. If the bleed out to the surface of the conductive film 1 and element feature of the piled organic EL elements do not become problems, there are not any limits, but the polymer dispersion solution doesn't have preferably any surfactants (emulsifier) and any plasticizer etc. controlling forming film temperature.

The glass transition temperature (Tg) of the polyolefin copolymer of the present invention is not limited, but 25˜150° C. is preferable. If Tg is higher than 25° C., surface smoothness of the conductive film 1 improves and dropping in property of the conductive film 1 and the organic EL element equipped with the conductive film 1 after the environmental test is avoided. If Tg is 50˜80° C., the polyolefin copolymer particles can melt enough at the drying temperature of the producing conductive film 1. If Tg is higher than 80° C., the polyolefin copolymer particles cannot melt enough at the drying temperature of the producing conductive film 1, but the surface is not rough after drying. If a leak doesn't occur after piling the organic electroluminescent element etc. and the desired feature can be obtained, the form of the polyolefin copolymer particles can be maintained. Further, to make Tg higher than 150° C., a molecular structure must be strengthened and higher molecular weight is needed. It should be difficult to make these polymers disperse in the dispersion liquid after making these polymers shorter than 100 nm. The glass transition temperature Tg can be measured by differential scanning calorimeter (DSC-7 type made by Perkin Elmer Co.) at the rising temperature rate 20° C./min and calculated in accordance with JIS K7121 (1987).

A viscosity of the dispersion liquid of the polyolefin copolymer of the present invention is preferably 1˜5000 mPa·s, more preferably 5˜1000 mPa·s. If the viscosity of the dispersion liquid of the polyolefin copolymer is higher than 1 mPa·s, the viscosity of the whole dispersion liquid including the conductive polymer and the polyolefin copolymer becomes enough high. Enough accuracy of the edge can be obtained when the dispersion liquid is coated on the substrate 11, and desired film thickness can be obtained. Therefore, the property of the surface of the conductive film 1 and the organic EL element equipped with the conductive film 1 is homogenized. Further, if the viscosity of the dispersion liquid of the polyolefin copolymer is lower than 5000 mPa·s, the viscosity of the whole dispersion liquid including the conductive polymer and the polyolefin copolymer becomes not too high. The remaining of the dispersion liquid at the discharge port, when the dispersion liquid is coated on the substrate 11, is avoided. The adhesion of foreign substance on the surface of the conductive film is prevented. As shown, the viscosity of the dispersion liquid of the polyolefin copolymer is preferably 5˜1000 mPa·s in the view of homogeneity of the film thickness of the conductive film 1 and the adhesion of foreign substance on the surface.

A PH of the dispersion liquid of the polyolefin copolymer for producing the conductive film 1 is preferably 0.1˜11.0, more preferably 3.0˜9.0, further preferably 4.0˜7.0 in the view of the mutual solubility with the conductive polymer solution for mixing and conductivity of the mixed liquid of the polyolefin copolymer and the conductive polymer.

The dissociable groups used in the polyolefin copolymer of the present invention are anionic group (sulfonic acid and its salt, carboxylic acid and its salt, phosphonic acid and its salt etc.) and cationic group (ammonium salt etc.). Such dissociable groups are not limited especially, but preferably anionic group in the view of the mutual solubility with the conductive polymer. Amount of the dissociable groups is enough if the polyolefin copolymer is dispersible in the aqueous solvent, preferably as small as possible because drying load can be reduced in the production process. Further, the counter ions for anionic group and cationic group are not limited especially, but preferably hydrophobic and small amount in the view of property of the conductive film 1 and the piled organic EL elements equipped with the conductive film 1.

The methods for polymerizing the polyolefin copolymer of the present invention are different depending on the monomer groups, but for example Japanese Unexamined Patent Application Publication No. 11-199607, Japanese Unexamined Patent Application Publication No. 2002-265706, Japanese Unexamined Patent Application Publication No. 11-263848, Japanese Unexamined Patent Application Publication No. 2005-206753 are showing methods for polymerizing the polyolefin copolymer.

A framework of the polyolefin copolymer of the present invention is preferably composed of α-olefins. α-olefins are not limited particularly, but for example, aliphatic α-olefins, alicyclic α-olefins, and aromatic α-olefins etc. are preferable. The aliphatic α-olefins are, for example, ethylene, propylene, 1-butene, 3-methyl-1-butene, 3,3-dimethyl-1-butene, 1-pentene, 4-methyl-1-pentene, 4,4-dimethyl-1-pentene, 1-hexene, 3-methyl-1-hexene, 4-methyl-1-hexene, 1-octene, 1-desene, 1-dodesene, 1-tetradesene, 1-hexadesene, 1-octadesene, 1-eicosen etc. The alicyclic α-olefins are, for example, allyl-cyclohexane, vinyl-cyclopropane, vinyl-cyclohexane etc. Further, aromatic α-olefins are, for example, styrene, allyl-benzene etc. The aliphatic α-olefins are preferable in those compounds in the view of reactivity, easiness of production and cost, more preferable are ethylene, propylene, and butadiene.

The polyolefin copolymers of the present invention are not limited, if they are composed of polyolefin and copolymer, they are polyethylene-polymethacrylic acid, polyethylene-polyacrylic acid, polyethylene-polyvinylalcohol (PVA), polyethylene-polyvinyl acetate, polyethylene-polyvinyl acetate-polymethacrylic ester, polyethylene-polyvinyl acetate-polyacrylic ester, polyethylene-polyvinyl acetate-polyvinyl chloride, polyethylene-polyvinyl chloride, polyethylene-polyvinyl chloride-polymethacrylic acid, polyethylene-polyvinyl chloride-polyacrylic acid, polyethylene-polyvinyl chloride-polymethacrylic ester, polyethylene-polyvinyl chloride-polyacrylic ester, polyethylene-polyurethane, polybutadiene-polystyrene etc. Further, based on these frameworks, copolymer using the other monomer can be a main framework. In these polymers, polyethylene-polymethacrylic acid, polyethylene-polyacrylic acid, polyethylene-polyvinyl acetate, and polybutadiene-polystyrene are preferable, polyethylene-polymethacrylic acid, polyethylene-polyacrylic acid are more preferable.

The commercial products of the polyolefin copolymer are given as follows: Panflex OM4200NT (polyethylene-polyvinyl acetate made by Kuraray Co.), Polysol AD-10 (polyethylene-polyvinyl acetate made by Showa Denko Co.), Polysol AD-11 (polyethylene-polyvinyl acetate made by Showa Denko Co.), Polysol P550N (polyethylene-polyvinyl acetate -polyvinyl ester made by Showa Denko Co.), Mowinyl 81F (polyethylene-polyvinyl acetate made by the Nippon Synthetic Chemical Industry Co.), Mowinyl 109E (polyethylene-polyvinyl acetate made by the Nippon Synthetic Chemical Industry Co.), Mowinyl 180E (polyethylene-polyvinyl acetate made by the Nippon Synthetic Chemical Industry Co.), Mowinyl 185EK (polyethylene-polyvinyl acetate made by the Nippon Synthetic Chemical Industry Co.), Sumika Flex 400HQ (polyethylene-polyvinyl acetate made by the Sumitomo Chemical Co.), Rica Bond BC-331C (polyethylene-polyvinyl acetate made by Chuo Rica Kogyo Co.), Hitech S-3121 (polyethylene-polymethacrylic acid made by Toho Chemical Industry Co.), Hitech S-3148 (polyethylene-polymethacrylic acid made by Toho Chemical Industry Co.), Hitech S-8512 (polyethylene-polymethacrylic acid made by Toho Chemical Industry Co.), Hitech S-9242 (polyethylene-polymethacrylic acid made by Toho Chemical Industry Co.), Rica Bond AC-3100 (polyethylene-polymethacrylic acid made by Chuo Rica Kogyo Co.), Zaikthene A (polyethylene-polyacrylic acid made by Sumitomo Seika Co.), Zaikthene L (polyethylene-polyacrylic acid made by Sumitomo Seika Co.), Zaikthene N (polyethylene-polyacrylic acid made by Sumitomo Seika Co.), Lack Star 7200A (carboxyl-polymethylmethacrylate-polybutadiene made by DIC Co.), SB Latex L2301 (polybutadiene-polystyrene made by Asahi Kasei Chemicals Co.), SB Latex L3200 (polybutadiene-polystyrene made by Asahi Kasei Chemicals Co.), SB Latex L5930 (polybutadiene-polystyrene made by Asahi Kasei Chemicals Co.), Nipol LX438C (polybutadiene-polystyrene made by Zeon Co.), Adectite HA050 (acryl grafted polybutadiene-polystyrene made by Asahi Kasei Chemicals Co.), Dinaflow CS1201 (polyisoprenesulfonic acid-polystyrene made by JSR Co.), Dinaflow CS1202 (polyisoprenesulfonic acid-polystyrene made by JSR Co.) etc. Further, the polyolefin copolymer can be comprised of one or more of the above polymers.

### Fine Particle

The fine particle of the present invention is a fine particle of inorganic material or organic material. A mean diameter of the fine particle is preferably 2˜500 nm, more preferably 5˜100 nm. If the mean diameter of the fine particle is smaller than 500 nm, the roughness of the conductive film 1 is suppressed and good feature can be obtained. Further, if the mean diameter of the fine particle is bigger than 2 nm, the generation of aggregation of each particle is suppressed, and dispersibility of the dispersion liquid improves. As a result, Hays level and smoothness (surface roughness (Ra)) of the conductive film 1 improve. The composition of the fine particle is not specially limited, for example, an inorganic fine particle with single inorganic material, an inorganic fine particle with complex inorganic material, an organic fine particle with single organic material, an organic fine particle with complex organic material, the fine particle coated with a organic polymer on a inorganic particle, on the contrary, the fine particle coated with inorganic material on a organic particle (including core-shell structure) are pointed out. In the case of inorganic and/or organic complex particle, for example, the inorganic particle is coated with the inorganic particle, the organic particle is coated with the organic particle, the organic particle is coated with the inorganic particle, the inorganic particle is coated with the organic particle, these combination can be considered. The binding pattern of the coating material can be physical biding with the core in center or chemical binding. The shape of the fine particle is not especially limited, but spherical type, needle type, board type, squamous, granular type etc. any shape and not limited, but preferably spherical type and the shape similar to sphere.

The binding pattern between the fine particle of the present invention and the conductive polymer and the polyolefin copolymer, which constitute the organic layer, can be physical binding or chemical binding. The physical binding means, for example, that the conductive polymer or the polyolefin copolymer can be binding partially into a porous fine particle. The chemical binding means, for example, that the conductive polymer or the polyolefin copolymer can be binding chemically with the fin particle.

The advantage of using the particle of the present invention is thought as following. The usage of the fine particle makes homogeneous fine pores in the whole organic compound layer, and a network of the fine pores can be formed. The conductive polymer and polyolefin copolymer can extend through the space of the network of the fine pores, and a conductive passage can be formed. If the amount of the conductive polymer and polyolefin copolymer is reduced, the load of drying element is reduced. Further, a rout of volatilized water from the inside of the forming layer to surface can be obtained because of the network structure of the fine pores. Therefore the volatility of the water when layer is formed by drying can be improved. By these ways, minimum amount of the conductive polymer can make effective conductive passage, and the present inventors estimate that achievement of both the conductivity and transparency.

The inorganic materials of the inorganic particle of the present invention are, for example, silicon dioxide, calcium carbonate, magnesium carbonate, calcium oxide, zinc oxide, magnesium oxide, sodium silicate, aluminum oxide, iron oxide, zirconium oxide, barium sulfate, titanium oxide, stannic oxide, antimony trioxide, carbon black, molybdenum disulfide and the mixture of these particles. The inorganic material of the inorganic particle is preferably silicon dioxide especially.

Further, the inorganic particle has preferably particle shape. The preferable inorganic particle has the primary particle size of smaller than 100 nm and the secondary particle size of smaller than 500 nm. Such inorganic particles are shown in following Japanese Unexamined Patent Application Publications. For example, No. Heisei1-97678, No. Heisei 2-275510, No. Heisei 3-281383, No. Heisei 3-285814, No. Heisei 3-285815, No. Heisei 4-92183, No. Heisei 4-267180, No. Heisei 4-275917 disclose almina hydrate which is boehmite sol. No. Shouwa 60-219083, No. Shouwa 61-19389, No. Shouwa 61-188183, No. Shouwa 63-178074, No. Heisei 5-51470 disclose colloidal silica. Japanese Patent Publication No. 4-19037and Japanese Unexamined Patent Application Publication No. Shouwa 62-286787 disclose silica/alumina hybrid sol. Japanese Unexamined Patent Application Publications No. Heisei 10-119423 and Heisei JP10-217601 disclose silica sol, which is dispersed by the high speed homogenizer for the gas phase process silica. And others are smectite clay of hektite, montmorillonite etc. (Japanese Unexamined Patent Application Publication No. Heisei 7-81210), zirconia sol, chromia sol, yttria sol, ceria sol, iron oxide sol, zircon sol, antimony oxide sol etc. Especially in these inorganic fine particles, colloidal silica can be used preferably.

The colloidal silica preferably used in the present invention is modified colloidal silica which surface is coated with the ion of calcium or with the compound of alumina to change the property of ion and behavior to the pH change, as well as non-modified colloidal silica of prior art.

The commercially available colloidal silica are preferably used in the present invention. For example, Snowtex 20, Snowtex 40, Snowtex N, Snowtex O, Snowtex S, Snowtex 20L, Snowtex AK, Snowtex UP etc. made by Nissan Chemical Industries Co, Silicadol 20, Silicadol 20A, Silicadol 20G, Silicadol 20P etc. made by Nippon Chemical Industrial Co., Adelite AT-20, Adelite AT-20N, Adelite AT-30A, Adelite AT-20Q etc. made by ADEKA Co., Ludox HS-30, Ludox LS, Ludox SM-30, Ludox AS, Ludox AM etc. made by Du Pont Co. can be pointed out.

The organic materials of the fine particle of the present invention are acryl resin, styrene resin, styrene-acryl resin, divinylbenzen resin, acrylonitrile resin, silicon resin, urethane resin, melamine resin, styrene-isoprene resin, fluoro resin, benzoguanamine resin, phenol resin, nylon resin, polyethylene wax and other reactive microgel etc. In these organic materials of the fine particle, acryl resin and styrene resin can be used preferably.

The commercially available organic fine particles are preferably used in the present invention. The examples of the commercial organic fine particles are given as follows: Taftic F167 (poly methyl methacrylate, 300 nm), Taftic F120 (polyacrylonitrile, 200 nm) made by TOYOBO Co., 3020A (polystyrene, 21 nm), 3030A (polystyrene, 33 nm), 3040A (polystyrene, 40 nm), 3050A (polystyrene, 46 nm), 3060A (polystyrene, 60 nm), 3070A (polystyrene, 73 nm), 3080A (polystyrene, 81 nm), 3090A (polystyrene, 92 nm), 3100A (polystyrene, 97 nm), 5003A (polystyrene, 30 nm), 5006A (polystyrene, 60 nm), 5009A (polystyrene, 90 nm), 5020A (polystyrene, 200 nm) made by Moritex Co.

The fine particles of the present invention can be various combinations of particles, which are the only inorganic fine particle, the mixture of several species of inorganic fine particles, the only organic fine particle, the mixture of several species of organic fine particles or the mixture of the inorganic fine particle and the organic fine particle etc.

### Conductive Polymer

“Conductive” means in the present invention that electric current flows and the sheet resistance measured by the manner depending on JIS K 7194 “method for measuring specific resistance of conductive polymers with 4 probes” is lower than 1×10⁸Ω/□.

The conductive polymer in the present invention means conductive polymer having cationic π conjugated conductive polymer and polyanion. These conductive polymer can be easily produced by chemical oxidation polymerization of the precursor monomer for the cationic π conjugated conductive polymer in the presence of appropriate oxidant, oxidation catalyst and polyanion.

### Cationic π Conjugated Conductive Polymers

The cationic π conjugated conductive polymers in the present invention are not limited, and are polythiophene (including the basic polythiophene, and so on) group, polypyrrole group, polyindole group, polycarbazole group, polyaniline group, polyacetylene group, polyfuran group, poly(paraphenylenevinylene) group, polyazulene group, polyparaphenylene group, poly(paraphenylenesulfide) group, polyisothianaphtene group, polythiazyl group of the conductive chain polymer. The cationic π conjugated conductive polymer is preferably polythiophene group or polyaniline group in the view of the conductivity, transparency and safety, more preferably poly(ethylenedioxythiophene).

### Precursor Monomer of Cationic π Conjugated Conductive Polymers

The precursor monomer for cationic π conjugated conductive polymers of the present invention has a π conjugated structure in the molecule. When the precursor monomers are polymerized by the appropriate oxidant, the main chain of the polymer has π conjugated structure. Such precursor monomers are, for example, pyrrole group and its derivatives, thiophene group and its derivatives and aniline group and its derivatives.

The precursor monomers are given, for example, pyrrole, 3-methylpyrrole, 3-ethylpyrrole, 3-n-propylpyrrole, 3-butylpyrrole, 3-octylpyrrole, 3-decylpyrrole, 3-dodecylpyrrole, 3,4-dimethylpyrrole, 3,4-dibutylpyrrole, 3-carboxylpyrrole, 3-methyl-4-carboxylpyrrole, 3-methyl-4-carboxyethylpyrrole, 3-methyl-4-carboxybutylpyrrole, 3-hydroxypyrrole, 3-methoxypyrrole, 3-ethoxypyrrole, 3-butoxypyrrole, 3-hexyloxypyrrole, 3-methy-4-hexyloxypyrrole, thiophene, 3-methylthiophene, 3-ethylthiophene, 3-propylthiophene, 3-butylthiophene, 3-hexylthiophene, 3-heptylthiophene, 3-octylthiophene, 3-decylthiophene, 3-dodecylthiophene, 3-octadecylthiophene, 3-bromothiophene, 3-chlorothiophene, 3-iodothiophene, 3-cyanothiophene, 3-phenythiophene, 3,4-dimethylthiophene, 3,4-dibutylthiophene, 3-hydroxythiophene, 3-methoxythiophene, 3-ethoxythiophene, 3-butoxythiophene, 3-hexyloxythiophene, 3-heptyloxythiophene, 3-octyloxythiophene, 3-decyloxythiophene, 3-dodecyloxythiophene, 3-octadecyloxythiophene, 3,4-dihydroxythiophene, 3,4-dimethoxythiophene, 3,4-diethoxythiophene, 3,4-dipropoxythiophene, 3,4-dibutoxythiophene, 3,4-dihexyloxythiophene, 3,4-diheptyloxythiophene, 3,4-dioctyloxythiophene, 3,4-didecyloxythiophene, 3,4-didodecyloxythiophene, 3,4-ethylenedioxythiophene, 3,4-propylenedioxythiophene, 3,4-butenedioxythiophene, 3-methyl-4-methoxythiophene, 3-methyl-4-ethoxythiophene, 3-carboxythiophene, 3-methyl-4-carboxythiophene, 3-methyl-4-carboxyethylthiophene, 3-methyl-4-carboxbutylthiophene, aniline, 2-methylaniline, 3-isobutyaniline, 2-anilinesulfonic acid, and 3-anilinesulfonic acid.

### Polyanion

The polyanions for the conductive polymer of the present invention are the substituted or non-substituted polyalkylene, the substituted or non-substituted polyalkenylene, the substituted or non-substituted polyimide, the substituted or non-substituted polyamide, the substituted or non-substituted polyester and one of these copolymers which are comprised of the structural unit with anion group and the structural unit without anion group.

These polyanions are the polymers which solve the cationic π conjugated conductive polymers into solvent. Further, the anion groups of the polyanions work as dopant to the cationic π conjugated conductive polymers. The conductivity and heat resistance of the cationic π conjugated conductive polymers are improved. Further, if the polyanions are used on excess amount to the cationic π conjugated conductive polymers, the dispersibility and ability of forming film of the conductive polymer particle comprising the cationic π conjugated conductive polymers and polyanion are improved.

The anion groups of the polyanion are the functional groups which make chemical oxidation dope to the cationic π conjugated conductive polymers. Such anion groups are preferably, in the view of easy production and stability, monosubstituted sulfate ester group, monosubstituted phosphate ester group, phosphoric acid group, carboxyl group, sulfo group etc. Further, such anion groups are more preferably, in the view of doping effect to cationic π conjugated conductive polymers, sulfo group, monosubstituted sulfate ester and carboxyl group.

Concrete examples of the polyanion are polyvinylsulfonic acid, polystyrenesulfonic acid, polyallylsulfonic acid, ethyl polyacrylate sulfonic acid, butyl polyacrylate sulfonic acid, poly-2-acrylamide-2-methylpropanesulfonic acid, polyisoprenesulfonic acid, polyvinylcarboxylic acid, polystyrenecarboxylic acid, polyallylcarboxylic acid, polyacrylic carboxylic acid, polymethacrylic carboxylic acid, poly-2-acrylamide-2 methylpropanecarboxylic acid, polyisoprenecarboxylic acid, and polyacrylic acid etc. Further, polyanion can be mono-polymer of these monomers and co-polymer of more than 2 monomers.

Further, the polyanion can be the polymer having F (fluoro atom) within the molecule. As such polyanions, concrete examples are Nafion (made by Du Pont Co.) including perfluorosulfon groups and Flemion (made by Asahi Glass Co.) comprising perfluoro type vinyl ether including carboxylic group.

If a compound of sulfonic acid as polyanion is used, the conductive polymer layer can be formed by coating and drying, thereafter, the drying process by heat at 100° C.˜120° C. for longer than 5 min. is carried out, then microwave or near IR can be irradiated. Further depending on the case, only irradiation of microwave or near IR can be carried out without heat drying process.

Further, polystyrenesulfonic acid, polyisoprenesulfonic acid, ethyl polyacrylate sulfonic acid or butyl polyacrylate sulfonic acid is preferable among the compound of sulfonic acid.

Polymerization degree of the polyanion is preferably 10˜100000 in the view of dispersibility of the conductive polymer, more preferably 50˜10000 in the view of solubility in the solvent and conductivity.

Methods for producing polyanion are, for example, to introduce directly anion groups using acid into the polymer without anion groups, to oxidize the polymer without anion groups using sulfonating agent and to polymerize the polymerizable monomer with anion groups.

Polymerization of the polymerizable monomer with anion groups can be carried out in the solvent under the presence of oxidant and/or polymerization catalyst in the manner of oxidation polymerization or radical polymerization of polymerizable monomer with anion group. Concretely, specified quantity of the polymerizable monomer with anion group is solved in the solvent, constant temperature is maintained, therein solution of specified quantity of the oxidizing agent and/or polymerizing catalyst and solvent is added, the reaction is carried out in the specified time. The polymer obtained from the reaction is treated with solvent to prepare constant concentration. Further, in this method, the polymerizable monomer with anion group can be copolymerized with the polymerizable monomer without anion group.

Further, if the obtained polymer is salt of polyanion, it is preferably changed to acid of polyanion. The modifying methods to change the salt of polyanion to the acid of polyanion are ion exchange method using ion exchange resin, dialysis, ultrafiltration process etc., preferably ultrafiltration process in the view of easy process.

The rate of the cationic π conjugated conductive polymer included in the conductive polymer and the polyanion constituting the conductive polymer, that is, weight ratio of the polyanion to the cationic π conjugated conductive polymer is preferably 0.5˜25 in the view of the conductivity and the dispersibility.

If the weight ratio of the polyanion to the cationic π conjugated conductive polymer is lower than 25, the storage stability of the conductive film and the organic EL element using the conductive film is improved as well as improvement of conductivity because hydrophilic polyanion or amount of moisture held by the conductive polymer decreases. Further, if the weight ratio is higher than 0.5, the resistance of the conductive polymer decreases in accordance with the increase of the dopant, in addition to that, the effect of polyanion acting as protective colloid is strengthened, the stability of the particle increases, and the size of the particle is suppressed. In the view of the conductivity, particle stability and storage stability of the conductive film and the organic EL element using the conductive film, the weight ratio of the polyanion to the cationic π conjugated conductive polymer is preferably higher than 0.5 and lower than 25.

As a method for controlling the weight ratio of the polyanion to the cationic π conjugated conductive polymer, a method for controlling the amount of the polyanion used in the synthesis of the conductive polymer is pointed out. In this method, if the weight ratio of the polyanion to the cationic π conjugated conductive polymer is lower than 1.0, other polymer can be used together in the synthesis of the conductive polymer, because the conductive polymer particles are prone to be large. The polymers used together are not limited if conductive particle is stabilized and transmittance rate and conductivity do not drop in quality, but preferably polyacrylate of 2-hydroxyethyl acrylate etc. or aqueous dispersion polymer of the self dispersion type polymer containing dissociative group. Further, a commercially available PEDOT/PSS can be dried, distillated in azeotropic process with toluene or freeze-dried to remove water from the polymer, and becomes powder by prior art, then is washed with water to remove PSS or is ultrafiltrated to replace PSS by water. These processes can be used.

The precursor monomer forming the cationic π conjugated conductive polymer polymerizes in the chemical oxidation polymerization process in the presence of the polyanion to obtain the conductive polymer of the present invention. Oxidant used in such a process is applied to the oxidation polymerization of pyrrole disclosed in, for example, J. Am. Chem. Soc., 85, 454 (1963), which pointed out several oxidants. Such oxidants are used preferably because of practical reasons, low price and easy treatment. For example, iron (III) salt (for example, FeCl₃, Fe(ClO₄)₃, iron (III) salt including a organic acid and organic group), Hydrogen peroxide, potassium dichromate, alkali persulfate (for example, potassium persulfate, sodium persulfate), ammonium, alkali perborate, potassium permanganate, or cupper salt (for example, cupper tetrafluoroborate). In addition, as oxidants, air or oxygen under the presence of metal ion of catalyst amount (for example, iron ion, cobalt ion, nickel ion, molybdenum ion, vanadium ion) can be used. In those oxidants, using persulfate salt, ion (III) salt of inorganic acid including organic acid or ion (III) salt of inorganic acid including organic group has application advantage because they are not corrosive.

As examples of the ion (III) salt of inorganic acid including organic group, following oxidants are pointed out. Ion (III) salt of sulfate half ester of alkanol of C1˜20 (for example, laurylsulfate), alkylsulfonate of C1˜20 (for example, methane, dodecanesulfonate), carbonate of aliphatic C 1˜20 (for example, 2-ethylhexylcarboxylic acid), aliphatic perfluorocarbonate (for example, trifluoroacetate, perfluorooctanoate), aliphatic dicarbonate (for example, oxalic acid), sulfonate of aromatic group of alkyl substitute of C 1˜20 (for example, Fe (III) salt of benzenesulfonic acid, p-toluenesulfonic acid, and dodecylbenzenesulfonic acid)

Some commercially available materials can be preferably used as the conductive polymer. For example, conductive polymer (PEDOT-PSS) which comprises poly(3,4-ethylenedioxythiophene) and polystyrenesulfonic acid, can be purchased as Clevios Series from Hereaus Co., 483095, 560596 of PEDOT-PSS from Sigma-Aldrich Co, Denatron Series from Nagase Chemtex Co. Further, polyaniline is sold as Ormecon Series from Nissan Chemical Industries Co. These agents can be used as the conductive polymer in the present invention.

The conductive polymer can include organic compound as the second dopant. The organic compound used in the present invention is not especially limited, and can be chosen among the prior art. For example, oxygen-containing compound is preferably pointed out. Said oxygen-containing compound is not limited if the compound contains oxygen atom. For example, hydroxyl-containing compound, carbonyl-containing compound, ether-containing compound and sulfoxide-containing compound are pointed out. As said hydroxyl-containing compound, for example, ethylene glycol, diethylene glycol, propylene glycol, trimethylene glycol, 1,4-butandiol, glycerin etc are pointed out. In these compound, ethylene glycol and diethylene glycol are preferable. As said carbonyl-containing compound, for example, isophorone, propylene carbonate, cyclohexanone, γ-butyrolactone etc. are pointed out. As said ether-containing compound, for example, diethylene glycol monoethyl ether etc. is pointed out. As said sulfoxide-containing compound, for example, dimethyl sulfoxide etc. is pointed out. These can be used alone or in combination with other oxygen-containing compound. More than 1 compound are preferably chosen from dimethyl sulfoxide, ethylene glycol, and diethylene glycol.

### Dispersion Liquid Comprising the Conductive Polymer and the Polyolefin Copolymer

The dispersion liquid including conductive polymer of the present invention and the self dispersible type polymer containing the dissociative groups is the aqueous liquid, in which the conductive polymer and polyolefin copolymer are dispersed. Said aqueous liquid is not only pure water (including distilled water and de-ionized water), but also solution containing acid, alkali and salt, organic solvent containing water or hydrophilic organic solvent. As the aqueous liquid, pure water (including distilled water and de-ionized water), alcoholic solvent of methanol, ethanol etc., mixed solvent of water and alcohol are pointed out.

The dispersion liquid of the present invention is preferably transparent, and not limited if the dispersion liquid can form a film. Further, if the bleed out to the surface of the conductive film 1 and feature of the element piling the organic EL elements do not become a problem, it is not limited, but the dispersion liquid includes preferably no surfactants (emulsifier) supporting the micelle formation and no plasticizers controlling the temperature of forming film.

The pH of the dispersion liquid of the present invention is not problem if desired conductivity is obtained, but preferably 0.1˜7.0, more preferably 0.3˜5.0.

Organic solvent can be added to control the surface tension of the dispersion liquid of the present invention. The organic solvent is not limited if desired surface tension is obtained, preferably alcohol of monool, diol or polyol. Boiling point of the organic solvent is preferably lower than 200° C., more preferably lower than 150° C.

Size (mean diameter) of conductive polymer and polyolefin copolymer after dispersion treatment included in the dispersion liquid of the present invention is preferably 1˜100 nm, more preferably 3˜80 nm, further preferably 5˜50 nm. If the particle size in the dispersion liquid is smaller than 100 nm, Hays level and smoothness (roughness (Ra)) of the second conductive layer (one of conductive layers) 13 which is generated by coating with the dispersion liquid on the substrate 11, are improved and further features of the organic electroluminescent element are improved. Further, if the particle size in the dispersion liquid is bigger than 1 nm, generation of aggregation is suppressed and dispersibility of the dispersion liquid improves, as a result, Hays level and smoothness (roughness (Ra)) of the second conductive layer (one of conductive layers) 13 are improved. The particle size in the dispersion liquid is preferably 3˜80 nm, more preferably 5˜50 nm to improve the smoothness of forming film. The temperature of forming film should be preferably controlled, because a film cannot be formed at the temperature of drying and particle shape remains even though a particle diameter is controlled, if the temperature of forming film of polyolefin copolymer in use is too high.

The methods of controlling the mean particle diameter of the dispersion liquid in the desired range are dispersion technology using homogenizer, ultrasonic disperser (US disperser), ball mill, etc. and classification technology of particles using reverse osmosis membrane, ultrafiltration membrane, precision filtration film. The temperature of the dispersion process is preferably −10° C.˜50° C., more preferably 0° C.˜30° C. because the particle can become bigger in the dispersion process using ball mill if temperature becomes very high. If strong shear force cutting polymer is used in the dispersion process, the temperature of the dispersion liquid has tendency to become high, the conductive polymer conjugation can be cut by the heat and degradation of the feature can be caused. As result, if temperature becomes higher than 50° C., the particle diameter tends to small size and sheet resistance of the second conductive layer (one of conductive layers) 13, which generates from the dispersion liquid, could increase. Further, if organic solvent is included in the aqueous solvent and solvent doesn't solidified even at lower than 0° C. (for example, −10˜0° C.), dispersion process can be preferably carried out. Further, the dispersion liquid is water-rich, therefore viscosity increases at the temperature lower than 0° C. and load of stirring becomes heavy. Further, evaporation of the solvent occurs at higher than 30° C., the concentration of the dispersion liquid can easily change, as a result, the feature of the conductive film 13 can be influenced. Classification in diameter of the particle is not limited, if selection of the membrane on demand is made.

The polyolefin copolymer particle and the conductive polymer particle in the dispersion liquid of the present invention can be dispersed independent on each other particle and particle diameter can be addition of each particle diameter and each particle of different composition can be condensed. Further, each particle of different composition can be partially mixed in the process of dispersion, or completely mixed to form particle.

The used amount (solid amount) of polyolefin copolymer of the present invention to the conductive polymer's solid amount is preferably 50˜5000 weight %, more preferably 100˜3500 weight %, further preferably 200˜2000 weight %. The reason that the used amount of polyolefin copolymer to the conductive polymer is preferably 50˜5000 weight % is if more than 50 weight %, improvement of transmittance rate becomes enough (the conductive polymer absorbs the light in the range of visible wave length, therefore to improve transmittance rate, reducing the amount of the conductive polymer as possible in the range of no reduction of the conductivity is desired.), if less than 5000 weight %, the ratio of the conductive polymer doesn't become too small, and good conductivity can be obtained. In this way, for improving transmittance and avoiding conductivity's decrease, the used amount of the polyolefin copolymer to the conductive polymer is preferably 100˜3500 weight %, more preferably 200˜2000 weight %.

Measurement of particle diameter of the dispersion of the present invention is not limited. Preferably, dynamic light scattering, laser diffraction or picture imaging method, more preferably, dynamic light scattering is pointed out. Diameters of the polyolefin copolymer particle and the conductive polymer particle becomes unstable by dilution, therefore, dense particle size measurer directly without any dilution by solvent is preferable. As such dense particle size measurers, dense particle analyzer (made by Otska Electronics Co.), Zetasizer Nano Series (made by Malvern Instruments Co.) are pointed out.

The fine particle of the present invention can be added to the dispersion liquid of the present invention. Such a fine particle is preferably used partially replacing the polyolefin copolymer, which constitutes the organic compound layer, in the view of reduction of heat drying load and suppression of film thickness of the organic compound layer. The used amount of the fine particle is preferably 25˜75 weight % to the polyolefin copolymer of solid weight, more preferably 30˜60 weight % to the conductive polymer. The reason that the used amount of the polyolefin copolymer is preferably 25˜75 weight % to the conductive polymer if the amount is more than 25 weight %, reduction effect of heat drying load is enough, and if the amount is less than 75 weight %, film property of the organic compound layer is improved. In this way, the used amount of the polyolefin polymer to the polyolefin copolymer is preferably 25˜75 weight % of solid weight for obtaining reduction effect of heat drying and avoiding the degradation of film property of the organic compound layer.

### Metal Material

As shown in FIG. 1, the conductive film 1 of the embodiment of the present invention comprises the conductive film (second conductive layer 13 in FIG. 1) including the conductive polymer and polyolefin copolymer and conductive layer including metal material (the first conductive layer 12 in FIG. 1) patterned on the substrate 11.

The metal material is not limited, if it has conductivity, for example, it can be metal of gold, silver, copper, ion, nickel, chrome etc. and alloy of them. Especially, shape of the metal material is preferably metal particle or metal nano-wire in the view of patterning. The metal material is preferably silver in the view of conductivity.

The first conductive layer 12 is patterned with an opening 12a on the substrate 11 to form the transparent conductive film 1. The opening 12a is a part without the metal material on the substrate 11 and a translucent window. The pattern shape is not especially limited, for example, stripe, mesh or random mesh is preferable. An opening ratio, which is the ratio of the opening 12a to the whole surface of the conductive film 1, is preferably more than 80% in the view of transparency. The opening ratio is the ratio of part excluding the conductive part of no-translucence to the whole surface. For example, the conductive part of no-translucence has the shape of stripe or mesh, the opening ratio of stripe pattern of line width 100 μm, and the line spacing 1 mm is about 90%.

The line width of the pattern is preferably 10˜200 μm in the view of transparency and conductivity. If the line width of the thin line is more than 10 μm, desired conductivity can be obtained. Further, if the line width of the thin line is less than 200 μm, desired transparency can be obtain. Height of the thin line is preferably 0.1˜10 μm. If the height of the thin line is more than 0.1 μm, desired conductivity can be obtained. Further, if the height of the thin line is less than 10 μm, electric leak and no-homogeneity of the film thickness of the functional layer are prevented.

As a method for forming the first conductive layer 12 of stripe type or mesh type, some conventionally known methods can be used without particular restrictions. For example, metal layer can be formed on the whole substrate 11 and the metal layer can be treated with photolithographic method, then pattern can be formed. Concretely, metal layer is formed on the whole substrate 11 by one or more than 2 of the physical or chemical treating methods of printing, vapor deposition, spattering, plating etc. In the other way, metallic foil is piled on the substrate with adhesive agent, then etching is carried out using the photolithograph of prior art and the first conductive layer 12 patterned in desired stripe pattern or mesh pattern can be obtained. Metal species are not limited if it is conductive. Copper, iron, cobalt, gold, silver etc. can be used, but preferably silver and copper in the view of conductivity, more preferably silver.

As other methods, method for printing desired pattern by screen printing with ink including metal fine particle, method for plating after coating the desired pattern by photogravure or ink-jet with the catalyst-ink which can be plated or method for applying silver-halide photo technology are pointed out.

The method for applying silver-halide photo technology can be carried out by referring to, for example, [0076]˜[0112] and examples of Japanese Unexamined Patent Application Publications No. 2009-140750. The method for plating after coating the desired pattern by photogravure with the catalyst-ink can be carried out by referring to, for example, Japanese Unexamined Patent Application Publications No. 2007-281290.

Further, random mesh pattern is disclosed in, for example, Japanese Unexamined Patent Application Publications No. 2005-530005, which shows the method for making spontaneous random mesh structure of conductive fine particle by coating and drying the liquid including metal fine particle. Such a method is usable. Further, as other method, for example, Japanese Unexamined Patent Application Publications No. 2009-505358 discloses that coating and drying the coating liquid (dispersion) including nano-wire makes the random mesh structure of metal nano-wire. Such a method is usable, too.

The metal nano-wire means fibrous structure mainly composed of metal element. Especially, the metal nano-wire of the present invention means many fibrous structures with the diameter from atomic scale to nm scale.

As the metal nano-wire, mean length is preferably longer than 3 μm more preferably 3˜500 μm so that a metal nano-wire should form a long conductive passage. If length of the metal nano-wire is shorter than 500 μm, single wire can be expanded smoothly without overlapping the other metal nano-wire, as a result the film thickness of the first conductive layer 12 can be suppressed, and forming thin layer can be achieved and the transmittance is improved. Further, if the length of the metal nano-wire is longer than 3 μm, contact points of each other of the metal nano-wire increase, additional amount of metal nano-wire can be suppressed, and desired sheet resistance and the transmittance can be obtained. In this case, relative standard deviation of the length is preferably less than 40%. This is because the surface irregularity of the film thickness of the first conductive layer 12 and decrease of the homogeneity of the sheet resistance are suppressed. Further, mean minor axis is not limited, but preferably small in the view of the transmittance, and on the other hand, it is preferably large in the view of the conductivity. Therefore, mean minor axis of the metal nano-wire is preferably 10˜300 nm, more preferably 30˜200 nm. In addition, relative standard deviation of the minor axis is preferably less than 20%. If the relative standard deviation of the minor axis is less than 20%, generation of the surface irregularity of the film thickness of the first conductive layer 12 can be suppressed, and generation of the surface irregularity of the brightness of the organic EL element can be suppressed. Weight of the metal nano-wire is preferably 0.02˜0.5 g/m². If the weight of the metal nano-wire is more than 0.02 g/m², the desired sheet resistance can be obtained, if the weight is less than 0.5 g/m², the desired sheet resistance and transmittance can be obtained. The weight of the metal nano-wire is preferably 0.03˜0.2 g/m², in the view of sheet resistance and transmittance.

As metal used for the metal nano-wire, copper, iron, cobalt, gold, silver etc. are pointed out, but silver is preferable in the view of conductivity. Further, the metal can be used as single element, but metal of main element and more than one other metal element can be used at any ratio so that both of conductivity and stability (sulfurization resistance, oxidation resistance and migration resistance of the metal nano-wire) are achieved.

Method for producing the metal nano-wire is not limited, for example, prior art of liquid phase method, gaseous phase method, etc. can be used. Further, concrete method for producing is not limited, and the prior art can be used. For example, The method for producing silver nano-wire can be referenced to “Adv. Mater., 2002, 14, 833˜837,” “Chem. Mater., 2002, 14, 4736˜4745,” the method for producing gold nano-wire can be referenced to Japanese Unexamined Patent Application Publications No. 2006-233252 etc., the method for producing copper nano-wire can be referenced to Japanese Unexamined Patent Application Publications No. 2004-149871. Especially, the method for producing silver nano-wire disclosed in upper document shows that silver nano-wire can easily produced in aqueous liquid and can be applied to the present invention because silver has the best conductivity in the metals.

Further, specific surface resistance of fine wire part (the first conductive layer 12) made of metal material is preferably less than 100Ω/□, more preferably 20Ω/□ in the view of increasing area. The specific surface resistance can be measured, for example, with JIS K6911 or with ASTM D257 etc. and easily measured with probe for surface resistivity measurement, which is sold in the market.

Further, the fine wire part (the first conductive layer 12) made of metal material is preferably treated with heat in the temperature range, which doesn't give damage to the substrate 11. By heat treatment, fusion bonding between metal particles or metal nano-wires proceeds, and the fine wire part made of metal material becomes high conductive.

### Substrate

The substrate 11 is board supporting the conductive layer 12, 13. If total light transmittance in the range of visible wave length measured with the method JIS K 7361-1: 1997 (method for testing total light transmittance of plastic transparent material) is more than 80%, then it is preferably used.

The substrate 11 which is flexible, and has enough small dielectric loss coefficient, and comprises the material having smaller absorption of microwave than the conductive layer 12, 13, is preferably used.

As the substrate 11, for example, resin substrate and resin film etc are preferably pointed out. The transparent resin film is preferably used, in the view of productivity, lightweight property and softness. The transparent resin film means the film which has more than 50% of total light transmittance in the range of visible wave length measured with the method JIS K 7361-1: 1997 (method for testing total light transmittance of plastic transparent material).

Preferably usable transparent resin film is not especially limited and material, shape, structure and thickness etc. can be suitably chosen among the prior art. As such transparent resin film, for example, polyester group resin film of polyethylene telephthalate (PET), polyethylene naphthalate, modified polyester etc., polyolefin group resin film of polyethylene film, polypropylene film, polystyrene film, cycloolefin resin etc., vinyl group film of polyvinyl chloride, polyvinylidene chloride etc., polyether ether ketone (PEEK) resin film, Polysulfon (PSF) resin film, polyethersulfon (PES) resin film, polycarbonate (PC) resin film, polyamide resin film, polyimide resin film, acryl resin film, triacetyl cellulose (TAC) resin film etc. are pointed out.

If said total light transmittance of resin film is more than 80%, then the film is preferably used as the film substrate used as the substrate 11 of the present invention. Such film substrates are preferably biaxial stretching polyethylene telephthalate film, biaxial stretching polyethylene naphthalate film, polyethersulfon film or polycarbonate film in the view of transparency, heat resistance, easy-handling, strength and cost, more preferably biaxial stretching polyethylene telephthalate film and biaxial stretching polyethylene naphthalate film.

The substrate 11 of the present invention can be treated on the surface and supports easily adhesive layer to maintain wettability and adhesiveness of coating liquid (dispersion liquid). Prior art of the technology can be used for the surface treatment and easily adhesive layer.

As surface treatment, for example, surface activating treatments of corona discharge treatment, flame treatment, ultraviolet treatment, high frequency processing, glow discharge treatment, active plasma treatment, laser treatment etc. are pointed out.

Further, as the easily adhesive layer, polyester, polyamide, polyurethane, vinyl group copolymer, butadiene group copolymer, acryl group copolymer, vinylidene group copolymer, epoxy group copolymer etc. are pointed out. The easily adhesive layer can be monolayer, but can become more than two layers in order to make adhesiveness stronger.

Further, inorganic film, organic film or hybrid film of both of the films can be supported on the surface or on the back of the film substrate. The film substrate with such films should be preferably barrier film with water vapor permeability (25±0.5° C., relative humidity (90±2) % RH) of less than 1×10⁻³ g/(m²·24 h) measured with the method based on JIS K 7129-1992, further preferable is high barrier film with oxygen gas permeability of less than 1×10⁻³ ml/(m²·24 h·atm) measured with the method based on JIS K 7126-1987 and with water vapor permeability (25±0.5° C., relative humidity (90±2) % RH) of less than 1×10⁻³ g/(m²·24 h).

Materials for forming barrier film on the surface and on the back of the film substrate to obtain high barrier film are the materials which have function to suppress the permeability of the material degrading the device like water and oxygen etc., for example, silicon oxide, silicon dioxide, silicon nitride etc. are available. Further these inorganic layer and layer made of organic compound can be preferably piled up to improve the weakness of the barrier film. The order of piling the layers of inorganic and organic layers is not limited, but preferably both of them are alternately and multiply piled up.

### Coating, Heating and Drying

The second conductive layer 13 of the present invention is formed after the coating liquid (dispersion liquid) including said conductive polymer and the polyolefin copolymer is coated on the substrate 11, and heated and dried. If the transparent conductive film 1 has the metal fine wire part as the first conductive layer 11, said coating liquid is coated on the substrate 11 on which the metal fine wire part is formed, and heated and dried to form the second conductive layer 13. Herein, the second conductive layer 13 should be electrically connected to the first conductive layer 12 of the metal fine wire part, The patterned metal fine wire part could be coated totally or partially or touched with the second conductive layer 13.

The available coating methods for the coating liquid comprising the conductive polymer and the polyolefin copolymer are printing method of gravure printing, flexography, screen printing etc. and, in addition to those methods, coating method of roll coating, bar coating, dip coating, spin coating, casting, die coating, blade coating, gravure coating, curtain coating, spray coating, doctor coating, ink jet coating can be used.

Further, as the method for producing the conductive film 1, which metal fine wire part (the first conductive layer 12) is partially coated by or touched by the second conductive layer 13 including the conductive polymer and polyolefin copolymer, it can be given a method which forms the first conductive layer on the transfer film in said manner and piles the second conductive layer 13 including the conductive polymer and polyolefin copolymer in the following manner and transfers the piled layers onto said substrate 11.

Further, as the method for producing conductive film 1, it can be given the other method that the second conductive layer 13 including the conductive polymer and polyolefin copolymer can be formed by the prior art like ink jet method etc. on the no-conductive part (opening part 12a) of the metal fine wire part.

The second conductive layer 13 including the conductive polymer and polyolefin copolymer preferably has the conductive polymer, to which the weight ratio of the polyanion to cationic π conjugated conductive polymer (the conductive polymer) is preferably higher than 0.5 and lower than 25. Thereby, high conductivity, high transparency and strong film strength can be obtained.

High conductivity, which cannot be obtained by metal fine wire or metal oxide fine wire or single conductive polymer layer alone, can be obtained homogeneously on the surface of the conductive film 1 by forming the conductive layer 12, 13 of the present invention with these structures.

The dried film thickness of the second conductive layer 13 is preferably 30˜2000 nm in the view of surface smoothness and transparency, more preferably more than 100 nm in the view of conductivity, further preferably more than 200 nm in the view of surface smoothness of the conductive film 1. Further, the dried film thickness of the second conductive layer 13 is preferably less than 1000 nm in the view of transparency.

The second conductive layer 13 is formed by coating the coating liquid (dispersion liquid) including the conductive polymer and the polyolefin copolymer and drying the liquid. The condition of drying treatment is not especially limited, but drying treatment is preferably performed at the temperature in the range of no-damage of the substrate 11 and the conductive layer 12, 13. For example, drying treatment at 80˜120° C. for 10 seconds˜10 minutes can be performed. By this treatment, cleaning resistance and solvent resistance of the conductive film 1 are remarkably improved, further the feature of the element is improved. Especially, drive voltage decreases and its life time increases in the case of the organic EL element equipped with the conductive film 1.

Said coating liquid can include plasticizer, stabilizer (anti-oxidation agent, anti-sulfurization agent etc.), surfactant, dissolution accelerator, polymerization inhibitor, coloring agent (dye, pigment etc.) etc. as addition agents. Further, said coating liquid can include solvent (for example, water, alcohol, glycol, cellosolve, ketone, ester, ether, amide, organic solvent of hydrocarbon etc.) in the view of improvement of working property of coating property etc.

In the present invention, Ry and Ra show the smoothness of the surface of the second conductive layer 13. Ry means maximum height (difference between the top of the mountain and the bottom of the valley of the surface) and Ra means arithmetical mean roughness based on the surface roughness defined in JIS B601 (1994). The conductive film 1 of the present invention has the second conductive layer 13, which surface smoothness preferably Ry≦50 nm and surface smoothness Ra≦10 nm. In the present invention, atomic force microscope (AFM) sold in the market can be used for the measurement of Ry and Ra, and the measurement can be performed as following manner.

SPI3800N probe station and SPA400 multifunctional unit made by Seiko Instruments Co. are used as AFM. Sample is cut in the size of 1 square cm. Sample is set on a horizontal specimen supported on a piezo scanner. A cantilever approaches sample surface and scans in XY direction after the cantilever achieves in the region of atomic force to work. Roughness of the sample can be measured by the piezo's change of position in the Z direction. A piezo scanner, which can scan a range of 20 μm in XY direction and a range of 2 μm in Z direction, is used. As the cantilever, silicon cantilever SI-DF20, which has resonance frequency 120˜150 kHz, spring constant 12˜20 N/m, made by Seiko Instruments Co. is used. Measurement is performed in DFM mode (Dynamic Force Mode). Measurement area 80×80 μm is measured with scanning frequency 1 Hz.

In the present invention, Ry value is preferably less than 50 nm in the view of improvement of conductivity, more preferably less than 40 nm. In the same way, Ra value is preferably less than 10 nm in the view of improvement of conductivity, more preferably less than 5 nm.

In the present invention, total light transmittance of the conductive film 1 is preferably more than 60%, more preferably more than 70%, further preferably more than 80%. The total light transmittance can be measured by the prior art of technology using spectrophotometer etc. Further, electric resistance of the second conductive layer 13 of the conductive film 1 of the present invention is preferably less than 600Ω/□ as surface resistivity in the view of improvement of the feature, more preferably less than 100Ω/□. Further, the surface resistivity is preferably less than 30Ω/□, more preferably less than 10Ω/□ in the view of feature improvement because of applying the conductive film 1 to the current drive type optoelectronics device. That is, if the surface resistivity of the second conductive layer 13 is less than 600Ω/□, the conductive film 1 can work appropriately as electrode in various optoelectronics device. Said surface resistivity can be measured, for example, based on JIS K 7194:1994 etc. (resistivity testing method of conductive plastics by four-point probe method), further, can be easily measured by a surface resistivity measurer sold in the market.

Thickness of the conductive film 1 of the present invention is not especially limited, can be chosen suitably depending on the aim, but is preferably less than generally 10 μm, if the thickness becomes thinner, transparency and softness are preferably improved.

### Organic EL Element

The organic EL element of the embodiment of the present invention is characterized by having the conductive film 1 as electrode. The organic EL element has an organic layer including an organic light emission layer and the conductive film 1. The organic EL element of the embodiment of the present invention has preferably the conductive film 1 as cathode. Any materials and structure which are used for organic EL elements are used for the organic light emission layer and an anode.

As the structures of the organic EL element, cathode/organic light emission layer/anode, cathode/hole transfer layer/organic light emission layer/electron transfer layer/anode, cathode/hole injecting layer/hole transfer layer/organic light emission layer/electron transfer layer/anode, cathode/hole injecting layer/organic light emission layer/electron transfer layer/electron injecting layer/anode, cathode/hole injecting layer/organic light emission layer/electron injecting layer/anode, etc. and various types of structures are pointed out.

Further, in the present invention, as light emission material or doping material for the organic light emission layer, anthracene, naphthalene, pyrene, tetracene, coronene, perylene, phthaloperylene, naphthaloperylene, diphenyl butadiene, tetraphenyl butadiene, coumarin, oxadiazole, bisbenzooxazoline, bisstyryl, cyclopentadiene, quinoline metal complex, tris(8-hydroxyquinolinate) aluminum complex, tris(5-phenyl-8-quinolinate) aluminum complex, aminoquinoline metal complex, benzoquinoline metal complex, tri-(p-terphenyl-4-il) amine, 1-aryl-2,5-di(2-thienyl) pyrrole derivatives, pyran, quinacridone, rubrene, distilbenzene derivatives, distilarylene derivatives, various fluorescent dye, rare earth metal complex, phosphorescence emission material etc. are pointed out, but not limited. Further, light emission material chosen among these compounds 90˜99.5 part by weight, doping material 0.5˜10 part by weight are preferably included. The organic light emission layer is produced by the prior art of technology of vapor deposition, coating, transferring etc. using these materials. The thickness of the organic light emission layer is preferably 0.5˜500 nm, more preferably 0.5˜200 nm in the view of luminous efficiency.

The conductive film 1 of the embodiment of the present invention has both of high conductivity and transparency, and is used appropriately in the field of various optoelectronic devices of liquid crystal display panel, organic light emission element, inorganic electroluminescent element, electronic paper, organic solar battery, inorganic solar battery, etc. and electromagnetic wave shield, touch panel, etc. Therein, the organic EL element and organic thin film solar battery demand severely smoothness of the conductive film surface, and the conductive film is especially used in those fields.

Further, the organic EL element of the present invention is preferably used in the field of lighting because homogeneous and no-irregular emission can be performed. The organic EL element can be used as self-luminous display, backlight for liquid crystal, lighting etc.

### EXAMPLES

The present invention will be concretely explained with examples as following. The present invention is not limited by the examples. Further, explanation of example uses “part” and “%” which means “part by weight” and “weight %,” insofar as there is no particular remark otherwise stated.

### Production of the Polyolefin Copolymer of the Present Invention

Synthesis examples of the polyolefin copolymer dispersion liquid of the present invention and copolymer dispersion liquid of comparative examples are disclosed as following.

### Synthesis Example 1

### Synthesis of Polyolefin Polymer PO-1 (Ethylene-Vinyl Acetate Copolymer Dispersion Liquid of the Present Invention)

Into the pressure resistant 10-liter autoclave, which is equipped with an inlet of nitrogen gas, thermometer and stirrer, PVA-1 (polymerization degree 1700, saponification degree 88 mol %, PVA-217 made by Kuraray Co.) 212.2 g, ion-exchanged water 3888 g, L(+) sodium tartrate 2.54 g, sodium acetate 2.12 g, ferrous chloride 0.08 g were added and prepared, and were completely solved at 95° C., followed by cooling to 60° C. Then nitrogen gas purge is performed. Next, vinyl acetate 4472 g was added, then ethylene was pressurized to 45 kg/cm2 and introduced into the autoclave. 0.4% hydrogen peroxide aqueous solution 200 g was pressurized and introduced in 5 hours, and emulsion polymerization was carried out at 60° C. PH of the early stage of the polymerization was checked, and pH was 5.2. When the vinyl acetate remained 10%, ethylene was released until ethylene pressure 20 kg/cm²·3% hydrogen peroxide aqueous solution 10 g was pressurized and introduced, and polymerization continued. When vinyl acetate monomer remained 1.5% in the emulsion, ethylene was released, and cooled. After cooling, pH was checked, and pH was 4.8. Next, sodium hydrogen sulfite 4 g was added, and ethylene was released at 30° C., under reduced pressure of 100 mmHg for one hour. Pressure of a system in the autoclave returned to normal pressure by nitrogen gas, thereafter, t-butyl hydrogen peroxide 2 g was added, and stirred for two hours. When the polymerization finished, pH was checked, and pH was 4.7. This emulsion was filtrated with stainless wire nettings of 60 mesh, and ethylene-vinyl acetate copolymer resin emulsion, which had solid content concentration 54.4% and ethylene content 18 weight %, was obtained. Ion-exchanged water was added to this emulsion to make solid content concentration 25%. Then polyolefin polymer PO-1 was obtained.

### Synthesis Example 2

### Synthesis of Polyolefin Polymer PO-2 (Ethylene-Methacrylic Acid Copolymer Dispersion Liquid of the Present Invention)

Ethylene-methacrylic acid copolymer (methacrylic acid 20%) 62.5 g, KOH 4.74 g, ZnO 3.55 g, and ion-exchanged water 187.5 g were added into 300 ml autoclave, and the autoclave was sealed, then stirred at 150° C. for two hours and dispersion reaction was carried out. After reaction, the autoclave was cooled in an iced water bath, and fine white emulsion was obtained. Ion-exchanged water was added to the emulsion to prepare solid content concentration 25%. Then polyolefin polymer PO-2 was obtained.

### Synthesis Example 3

### Synthesis of Polyolefin Polymer PO-3 (Ethylene-Acrylic Acid Copolymer Dispersion Liquid of the Present Invention)

Ethylene-acrylic acid copolymer (acrylic acid 20%) 62.5 g, KOH 5.66 g, ZnO 4.24 g, and ion-exchanged water 187.5 g were added into 300 ml autoclave, and the autoclave was sealed, then stirred at 150° C. for two hours and dispersion reaction was carried out. After reaction, the autoclave was cooled in an iced water bath, and fine white emulsion was obtained. Ion-exchanged water was added to the emulsion to prepare solid content concentration 25%. Then polyolefin polymer PO-3 was obtained.

### Synthesis Example 4

### Synthesis of Polyolefin Polymer PO-4 (Ethylene-Methacrylic Acid Copolymer Dispersion Liquid of the Present Invention)

Ethylene-methacrylic acid copolymer (methacrylic acid 15%) 62.5 g, KOH 4.25 g, ZnO 3.18 g, and ion-exchanged water 187.5 g were added into 300 ml autoclave, and the autoclave was sealed, then stirred at 150° C. for two hours and dispersion reaction was carried out. After reaction, the autoclave was cooled in an iced water bath, and fine white emulsion was obtained. Ion-exchanged water was added to the emulsion to prepare solid content concentration 25%. Then polyolefin polymer PO-4 was obtained.

### Synthesis Example 5

### Synthesis of Polyolefin Polymer PO-5 (Butadiene-Styrene Copolymer Dispersion Liquid of the Present Invention)

Nitrogen purge was made in a 10-liter pressure resistant autoclave, then 1,3-butadiene 465 g, styrene 35 g, n-dodecyl mercaptan 1.0 g, potassium persulfate 1.5 g, sodium rosinate 5.0 g, sodium hydroxide 0.5 g and de-ionized water 650 g were added. The mixture was stirred and warmed to 70° C., thereafter temperature was maintained at 70° C. 12 hours later after reaching 70° C., when polymerization conversion rate of monomer became 90%, sodium formaldehyde sulfoxylate 1.0 g which was solved in de-ionized water 25 part, was added, later 70° C. was maintained for 2 hours, thereafter, the reaction was finished. Ion-exchanged water was added to the dispersion to prepare solid content concentration 50%, Then polyolefin polymer PO-5 was obtained.

### Synthesis Example 6

### Synthesis of Comparative Copolymer Dispersion Liquid PO-A (Polyester Copolymer Dispersion Liquid of the Comparative Compound)

### Synthesis Example of Polyester

Into a reaction vessel equipped with stirrer, thermometer and reflux condenser, terephthalic acid 75 g, isophthalic acid 75 g, 5-Na sulfo dimethyl isophthalate 10 g, ethylene glycol 100 g, neopentyl glycol 100 g, n-tetrabutyl titanate 0.1 g as catalyst, sodium acetate 0.3 g as polymerization stabilizer, Irganox 1330 2 g as oxidation inhibitor were added and prepared. Transesterification reaction was carried out at 170˜230° C. for two hours. After the transesterification reaction finished, reaction system was warmed from 230° C. to 270° C., on the other hand, pressure of the system was reduced slowly, at 270° C. until 5 Torr spending 60 minutes. Further, polycondensation reaction was carried out for 30 minutes under less than 1 Torr. After the polycondensation reaction finished, the pressure of the system increased from vacuum to normal pressure by nitrogen gas. Melted polyester (A) was obtained. Polyester (D) has, as a result of NMR analysis, element of dicarboxylic acid of terephthalic acid 49 mol %, isophthalic acid 48.5 mol % and 5-Na sulfo isophthalic acid 2.5 mol % and diol element of ethylene glycol 50 mol %, neopentyl glycol 50 mol %, and its glass transition temperature was 67° C., its reduced viscosity was 0.53 dl/g.

### Synthesis Example of Aqueous Dispersion

Reaction vessel, which was equipped with stirrer, thermometer and reflux condenser, contained polyester (D) 25 g after polycondensation reaction. Temperature of the system was cooled to 200° C. with continuing stirring under nitrogen gas atmosphere. After reaching the specific temperature, butyl sellosolve 15 g was added with continuing stirring, and the resin was solved with controlling the temperature of the system to be 80° C. After checking the resin's solving, water 55 g was added a little by a little with continuing stirring to obtain aqueous dispersion. Later aqueous dispersion was obtained by cooling the system. Ion-exchanged water was added to the obtained dispersion to prepare solid content concentration 25%, then comparative copolymer dispersion liquid PO-A was obtained.

### Synthesis Example 7

### Synthesis of Comparative Copolymer Dispersion Liquid PO-B (Acryl Copolymer Dispersion Liquid) (of the Comparative Compound)

Ion-exchanged water 137.4 g was added into a 500 ml four mouth flask, which was equipped with stirrer, temperature sensor, reflux condenser and monomer dropping port. Degassing and bubbling of nitrogen gas was performed several times until solving oxygen concentration became less than 0.5 mg/L. After deoxygenation, heating began. In the following emulsion polymerization process, bubbling of nitrogen gas continued. Acryl monomer mixture 100 g of methyl methacrylate 41.0 g, n-butyl methacrylate 54.0 g, 2-hydroxyethyl methacrylate 5.0 g, Adeka Reasoap SR-1025 (reactive emulsifier made by Adeka Co., 25% aqueous solution) 8.0 g, ion-exchanged water for pre emulsion production 39.7 g were mixed, and pre-emulsified by emulsifier's 10000 rotations for 10 minutes. When the temperature in the flask became 70° C., 10 wt % (14.8 g) of the pre-emulsion was added into the flask. When the temperature in the flask became 73° C. of the polymerization temperature, ammonium persulfate as polymerization initiator 0.2 g, was added, thereafter, emulsion polymerization was carried at 73° C. for 30 minutes, then seed emulsion was obtained. Remaining 90% (132.9 g) of pre-emulsion was dropped into the flask for 3 hours, after the end of dropping, further polymerization was carried at 73° C. for 30 minutes, then temperature was heated to 80° C. in 30 minutes, and aging reaction was carried out. After temperature reached 80° C., 30 minutes later, ammonium persulfate 0.020 g, ion-exchanged water 0.400 g were added, 30 minutes later, further ammonium persulfate 0.010 g, ion-exchanged water 0.200 g were added, after the end of dropping, aging reaction was carried out for 30 minutes. Flask was cooled down to 40° C., Adekanate B-1016 (antifoaming agent made by Adeka Co.) 0.005 g was added, further stirred for 30 minutes and mixed, further 25% ammonia solution 0.47 g was added to control pH, then acryl emulsion AE-1 was produced. The properties of the acryl emulsion AE-1 were as follows: 35.2% of solid content, 12.0 mPa·s, pH 8.5, and 135 nm of particle diameter. Ion-exchanged water was added to the obtained dispersion to prepare the solid content 25%. Thus, comparative copolymer dispersion liquid PO-B was obtained.

### Synthesis Example 8

### Synthesis of Comparative Copolymer Dispersion Liquid PO-C (Acryl-Styrene Copolymer Dispersion Liquid of the Comparative Compound)

Ion-exchanged water 100 g and PD-104 (polyoxyalkylene alkenyl ether ammonium sulfate made by Kao Co.) 0.1 g were added into a reaction vessel, which was equipped with thermometer, temperature controller, stirrer, dropping funnel, nitrogen gas introducing tube, reflux condenser. Temperature was rising to 80° C. and nitrogen gas was introduced. Next, styrene 20 g, methyl methacrylate 38 g, butyl methacrylate 41 g, PD-104 (polyoxyalkylene alkenyl ether ammonium sulfate made by Kao Co.) 1.5 g, ion-exchanged water 90 g were mixed and stirred by emulsifier at the speed 1000˜1500 rpm and pre-emulsion liquid was prepared separately and connected the dropping funnel. Temperature was maintained at 80° C., stirring at 100 rpm was performed, sodium persulfate 0.2 g was added, then the pre-emulsion liquid was dropped from the dropping funnel for 4 hours. After end of dropping, temperature was maintained at 80° C. and aging reaction was performed for 2 hours. Thereafter, aqueous dispersion liquid was cooled and its properties were as following. No-volatile content 35%, pH 2.5 and viscosity 50 mPa·s. Ion-exchanged water was added to the dispersion liquid to prepare solid content concentration 25%. Thus, the comparative copolymer dispersion liquid PO-C was obtained.

### Production of Substrate

No-undercoated surface of polyethylene terephthalate film of the thickness 100 μm (Cosmoshine A4100 made by Toyobo Co.) was coated with OPSTAR Z7501 (UV curable organic/inorganic hybrid hard coat material made by JSR Co.) by wire bar to make mean film thickness of 4 μm after coating and drying. Thereafter, the film was dried at 80° C. for 3 minutes. Then curing was performed in the condition of 1.0 J/cm² with high pressure mercury lamp in the air. Then the smooth layer was formed.

Next, a gas barrier layer was formed on the sample with said smooth layer in the following condition.

### Coating Liquid for the Gas Barrier Layer

Dibutyl ether solution of 20 weight % of perhydropolysirazane (PHPS, Aquamica NN320 made by AZ Electronic materials Co.) was coated with wireless bar so that the dried coating film became 0.30 μm. Then coated sample was obtained.

### The First Step; Drying Process

The obtained coated sample was dried for one minute at 85° C., in humidity 55% RH. Then a dried sample was obtained.

### The Second Step; Dehumidifying Process

The dried sample was dehumidified for ten minutes at 25° C., in humidity 10% RH (dew point −8° C.), and dehumidifying process was performed.

### Modification Process A

The sample after dehumidifying process was modified in the following condition to form a gas barrier layer on the sample. Dew point was −8° C. when modification process was performed.

### Modification Apparatus

Excimer irradiation apparatus made by M.D.Com Co., Model: MECL-M-1-200, wave length 172 nm, lamp filler gas Xe.

Modification process for the fixed sample on the operation stage was performed under the following condition.

### Modification Process Condition

| Excimer light strength | 60 mW/cm² (172 nm) | |
|---|---|---|
| Distance between the sample and the light | 1 | mm |
| source | | |
| Temperature of heating stage | 70° | C. |
| Oxygen concentration in the irradiation | 1% | |
| apparatus | | |
| Excimer irradiation time | 3 | seconds |

The film substrate (the substrate 11) for the conductive film (the conductive film 1) with gas bather property was produced by the upper processes.

### Example 1

### Preparation of Conductive Film

### Preparation of Conductive Film TC-101

Coating liquid A prepared as following was coated on the surface without bather of the film substrate for the conductive film with gas barrier property. Extruder was used to coat through the controlled slip gap of extruder's head and to prepare a dried film of thickness 300 nm. Then coated liquid layer was heated and dried at 110° C. for five minutes, and conductive film consisting of conductive polymer and olefin copolymer was formed, then obtained electrode was cut in the size of 8×8 cm square. The obtained electrode was heated at 110° C. for 15 minutes. Thereby the conductive film TC-101 was obtained.

### Coating Liquid A

The Coating liquid A was obtained from the following composition liquid after homogenizing twice with high pressure homogenizer in the condition of 71 kPa, nozzle diameter 0.1 mm, 5˜10° C.

Conductive polymer dispersion liquid: PEDOT/PSS CLEVIOS PH510 (solid content concentration 1.89%, made by H.C. Starck Co.) 20.0 g

Polyolefin copolymer dispersion liquid: PO-1 (solid content concentration 25%, solid content 882 mg) 3.5 g

Dimethyl sulfoxide (DMSO, 1/10 of the conductive polymer liquid's weight) 1.0 g

### Production of Conductive Films TC-102˜TC-108

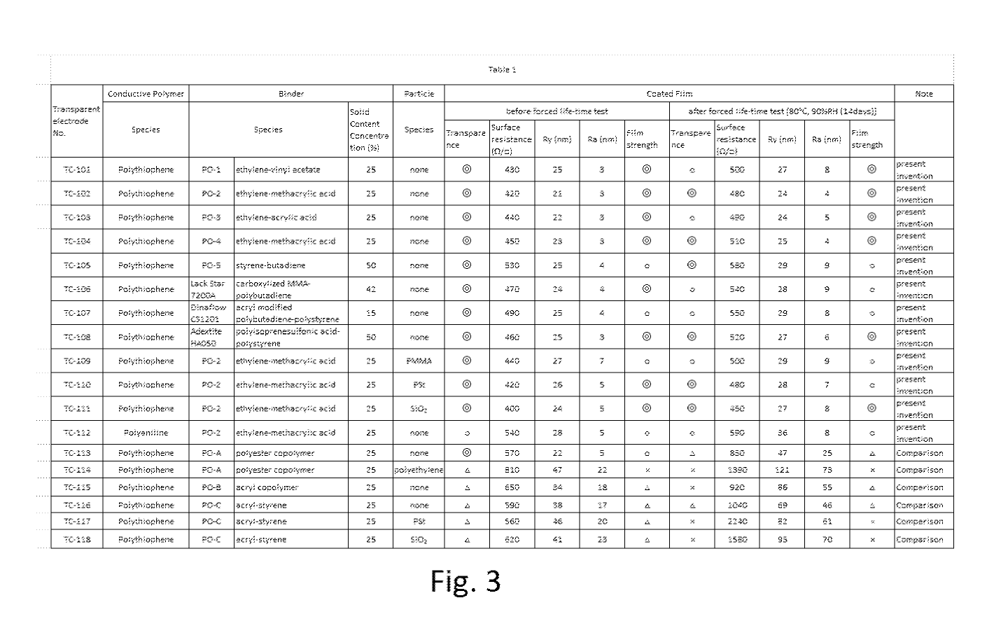

In the preparation of conductive film TC-101, polyolefin copolymer dispersion liquid of coating liquid A was exchanged as Table 1 (see also FIG. 3), and addition amount to the coating liquid A was changed to 882 mg. Conductive films TC-102˜TC-108 were produced in the same way as TC-101 except those changes.

### Production of Conductive Films TC-109˜TC-111

In the preparation of conductive film TC-102, half (441 mg) of the solid content weight of the polyolefin dispersion of the coating liquid A was changed to cross-linked PMMA fine particle (Taftic FH-S010, mean particle size 300 nm, solid content concentration 27% made by Toyobo Co.), polystyrene fine particle (5003A, mean particle size 30 nm, solid content concentration 10% made by Moritex Co.), colloidal silica (Snowtex O, mean particle size 18 nm, solid content concentration 20.6%, made by Nissan Chemical Industries Co.). Conductive films TC-109˜TC-111 were produced in the same way as TC-102 except that change.

### Production of Conductive Film TC-112

In the preparation of conductive film TC-102, PEDOT/PSS CLEVIOS PH510 of the coating liquid A was changed to polyaniline M (solid content concentration 6.0%, TA Chemical Co.) 6.3 g. Conductive film TC-112 was produced in the same way as TC-102 except that change

### Production of Comparative Conductive Film TC-113

In the preparation of conductive film TC-101, polyolefin copolymer dispersion liquid of coating liquid A was exchanged as Table 1 (see also FIG. 3), and addition amount to the coating liquid A was changed to 882 mg. Comparative conductive film TC-113 were produced in the same way as TC-101 except those changes.

### Production of Comparative Conductive Film TC-114

In the preparation of conductive film TC-113, half (441 mg) of the solid content weight of the polyolefin dispersion of the coating liquid A was changed to polyethylene particle (Ceracol 39, mean particle size 13000 nm, solid content concentration 40% made by BYK Chemie Co.). Comparative conductive film TC-114 was produced in the same way as TC-113 except that change

### Production of Comparative Conductive Films TC-115, TC-116

In the preparation of conductive film TC-101, polyolefin copolymer dispersion liquid of coating liquid A was exchanged as Table 1 (see also FIG. 3), and addition amount to the coating liquid A was changed to 882 mg. Comparative conductive film TC-115,TC-116 were produced in the same way as TC-101 except those changes.

### Production of Comparative Conductive Films TC-117, TC-118

In the preparation of conductive film TC-116, half (441 mg) of the solid content weight of the polyolefin dispersion of the coating liquid A was changed to polystyrene fine particle (5003A, mean particle size 30 nm, solid content concentration 10% made by Moritex Co.), colloidal silica (Snowtex O, mean particle size 18 nm, solid content concentration 20.6%, made by Nissan Chemical Industries Co.). Conductive films TC-117, TC-118 were produced in the same way as TC-116 except that change.

### Evaluation of the Conductive Films

Shape, transparency, surface resistance (conductivity), surface roughness and film strength of the obtained conductive films were evaluated as following. Further, after forced life-test of staying in the environment of 80° C., 90% RH for 14 days to evaluate stability of the conductive film, the film-shape, the transparency, the surface resistance, the surface roughness and the film strength of the tested conductive film samples were evaluated.

### Transparency

Total light transmittance rate was measured by HAZE Meter NDH5000 made by Tokyo Denshoku Co. based on JIS K 7361-1: 1997. Measured results were evaluated by a following standard. The results are preferably more than 75% to use for organic electric devices.

⊚: more than 80%

◯: 75%˜less than 80%

Δ: 70%˜less than 75%

×: less than 70%

Evaluation Standard: samples, which were evaluated as ⊚, ◯ after forced life-time test, came up to the standard of the present invention.

### Surface Resistance

Surface resistance was measured by resistivity meter (Loresta GP (MCP-T610) made by Mitsubishi Chemical Analytech Co.) based on JIS K 7194: 1994. Surface resistance is preferably less than 600Ω/□ to enlarge area of the organic electronic devices.

Evaluation Standard: Samples, which were evaluated and were less than 600Ω/□ after forced life-time test, came up to the standard of the present invention.

### Surface Roughness (Ra, Ry)

Samples cut in the size of 1 cm square were measured with AFM (SPI3800N Probe station and SPA400 multifunctional unit made by Seiko Instruments Co.) based on said method (roughness was defined by JIS B601 (1994)).

Evaluation Standard: Samples of Ry≦50 nm and Ra≦10 nm after forced life-time test came up to the standard of the present invention.

### Film Strength

Film strength of the conductive film was evaluated by peeling tape method.

Scotch tape made by Sumitomo 3M Co. was crimped and peeled ten times on the conductive film.

Dropping out of the conductive film was observed by visual observation, and evaluated by following standards.

⊚: No change was observed after 5 times crimping and peeling.

◯: No change was observed after 3 times crimping and peeling.

Δ: Dropping out was observed after only once crimping and peeling, but more than 80% of pattern remained

×: Dropping out was observed after only once crimping and peeling, and less than 80% of pattern remained

Evaluation Standard: samples, which were evaluated as ⊚, ◯ after forced life-time test, came up to the standard of the present invention.

The result of evaluation is shown in the Table 1 (also shown in FIG. 3).

TABLE 1

| | | Binder | | | | Coated Film | |
|---|---|---|---|---|---|---|---|
| | | | | Solid | | before forced life-time test | |
| Transparent | Conductive | | | Content | | | Surface |
| electrode | Polymer | | | Concentration | Particle | | resistance |
| No. | Species | Species | | (%) | Species | Transparence | (Ω/□) |
| TC-101 | Polythiophene | PO-1 | ethylene- | 25 | none | ⊚ | 430 |
| | | | vinyl acetate | | | | |
| TC-102 | Polythiophene | PO-2 | ethylene- | 25 | none | ⊚ | 420 |
| | | | methacrylic acid | | | | |
| TC-103 | Polythiophene | PO-3 | ethylene- | 25 | none | ⊚ | 440 |
| | | | acrylic acid | | | | |
| TC-104 | Polythiophene | PO-4 | ethylene- | 25 | none | ⊚ | 450 |
| | | | methacrylic acid | | | | |
| TC-105 | Polythiophene | PO-5 | styrene-butadiene | 50 | none | ⊚ | 530 |
| TC-106 | Polythiophene | Lack Star | carboxylized MMA- | 42 | none | ⊚ | 470 |
| | | 7200A | polybutadiene | | | | |
| TC-107 | Polythiophene | Dinaflow | acryl modified | 15 | none | ⊚ | 490 |
| | | C51201 | polybutadiene- | | | | |
| | | | polystyrene | | | | |
| TC-108 | Polythiophene | Adextite | polyisoprenesulfonic | 50 | none | ⊚ | 460 |
| | | HAO50 | acid-polystyrene | | | | |
| TC-109 | Polythiophene | PO-2 | ethylene- | 25 | PMMA | ⊚ | 440 |
| | | | methacrylic acid | | | | |
| TC-110 | Polythiophene | PO-2 | ethylene- | 25 | PSt | ⊚ | 420 |
| | | | methacrylic acid | | | | |
| TC-111 | Polythiophene | PO-2 | ethylene- | 25 | SiO₂ | ⊚ | 400 |
| | | | methacrylic acid | | | | |
| TC-112 | Polyaniline | PO-2 | ethylene- | 25 | none | ◯ | 540 |
| | | | methacrylic acid | | | | |
| TC-113 | Polythiophene | PO-A | polyester | 25 | none | ⊚ | 570 |
| | | | copolymer | | | | |
| TC-114 | Polythiophene | PO-A | polyester | 25 | polyethylene | Δ | 810 |
| | | | copolymer | | | | |
| TC-115 | Polythiophene | PO-B | acryl copolymer | 25 | none | Δ | 650 |
| TC-116 | Polythiophene | PO-C | acryl-styrene | 25 | none | Δ | 590 |
| TC-117 | Polythiophene | PO-C | acryl-styrene | 25 | PSt | Δ | 560 |
| TC-118 | Polythiophene | PO-C | acryl-styrene | 25 | SiO₂ | Δ | 620 |

| | Coated Film | | | | | | | | |
|---|---|---|---|---|---|---|---|---|---|
| | | | | after forced life-time test | | | | | |
| | | | | [80° C., 90% RH (14 days)] | | | | | |
| Transparent | before forced life-time test | | | | Surface | | | | |
| electrode | Ry | Ra | Film | | resistance | Ry | Ra | Film | |
| No. | (nm) | (nm) | strength | Transparence | (Ω/□) | (nm) | (nm) | strength | Note |
| TC-101 | 25 | 3 | ⊚ | ◯ | 500 | 27 | 8 | ⊚ | present |
| | | | | | | | | | invention |
| TC-102 | 21 | 5 | ⊚ | ⊚ | 480 | 24 | 4 | ⊚ | present |
| | | | | | | | | | invention |
| TC-103 | 22 | 3 | ⊚ | ◯ | 490 | 24 | 5 | ⊚ | present |
| | | | | | | | | | invention |
| TC-104 | 23 | 3 | ⊚ | ⊚ | 510 | 25 | 4 | ⊚ | present |
| | | | | | | | | | invention |
| TC-105 | 25 | 4 | ◯ | ⊚ | 580 | 29 | 9 | ◯ | present |
| | | | | | | | | | invention |
| TC-106 | 24 | 4 | ⊚ | ◯ | 540 | 28 | 9 | ◯ | present |
| | | | | | | | | | invention |
| TC-107 | 25 | 4 | ◯ | ◯ | 550 | 29 | 8 | ◯ | present |
| | | | | | | | | | invention |
| TC-108 | 25 | 3 | ⊚ | ⊚ | 520 | 27 | 6 | ⊚ | present |
| | | | | | | | | | invention |
| TC-109 | 27 | 7 | ◯ | ◯ | 500 | 29 | 9 | ◯ | present |
| | | | | | | | | | invention |
| TC-110 | 26 | 5 | ⊚ | ⊚ | 480 | 28 | 7 | ◯ | present |
| | | | | | | | | | invention |
| TC-111 | 24 | 5 | ⊚ | ⊚ | 450 | 27 | 8 | ⊚ | present |
| | | | | | | | | | invention |
| TC-112 | 28 | 5 | ◯ | ◯ | 590 | 56 | 8 | ◯ | present |
| | | | | | | | | | invention |
| TC-113 | 22 | 5 | ◯ | Δ | 830 | 47 | 25 | Δ | Comparison |
| TC-114 | 47 | 22 | X | X | 1390 | 121 | 73 | X | Comparison |
| TC-115 | 34 | 18 | Δ | X | 920 | 86 | 55 | Δ | Comparison |
| TC-116 | 38 | 17 | Δ | Δ | 1040 | 69 | 46 | Δ | Comparison |
| TC-117 | 46 | 20 | Δ | X | 2240 | 82 | 61 | X | Comparison |
| TC-118 | 41 | 23 | Δ | X | 1580 | 93 | 70 | X | Comparison |

The Table 1 shows that the conductive film TC-101˜112 of the present invention have preferable smoothness, conductivity, light transmittance and film strength to the comparative conductive film TC-113˜118 and that degradation of smoothness, conductivity, light transmittance and film strength of the present invention under hot and humid environment is small and that the present invention has better stability.

### Example 2

### Forming of the Conductive Film

### Forming the First Conductive Layer

The first conductive layer was formed on the no-gas barrier surface of the film substrate (substrate 11) for the conductive film (conductive film 1) which has gas barrier as written in former description.

### Fine Wire Lattice

The fine wire (metal material) was obtained by following gravure printing or silver nano wire.

### Gravure Printing

Fine wire lattice of line width 50 μm, height 1.5 μm and interval 1.0 mm was printed by gravure printer (K303Multicoater made by RK print coat instruments Co.) with silver nano particle paste 1 (M Dot SLP made by Mitsuboshi belting Co.). Then drying treatment was performed at 110° C. for 5 minutes.

### Production of the Conductive Film TC-201

Following coating A was coated by controlled extrusion process on the conductive film, on which the first conductive layer was printed on the film substrate for the conductive film with gas barrier by gravure printing. The slit gap of extruder's head was controlled to make the dried layer 300 nm thick. Then coated layer was heated and dried at 110° C. for 5 minutes. The second conductive layer consisting of the conductive polymer and the olefin copolymer was formed. Obtained electrode was cut in the size of 8×8 cm. The obtained electrode was heated by oven at 110° C. for 15 minutes, and a conductive film TC-201 was produced.

### Forming the Second Conductive Layer 13

### Coating Liquid A

The Coating liquid A was obtained from the following composition liquid after homogenizing twice with high pressure homogenizer in the condition of 71 kPa, nozzle diameter 0.1 mm and at 5˜10° C.

Conductive polymer dispersion liquid: PEDOT/PSS CLEVIOS PH510 (solid content concentration 1.89%, made by H.C. Starck Co.) 20.0 g

Polyolefin copolymer dispersion liquid: PO-1 (solid content concentration 25%, solid content 882 mg) 3.5 g

Dimethyl sulfoxide (DMSO, 1/10 of the conductive polymer liquid's weight) 1.0 g

### Production of Conductive Films TC-202˜TC-208

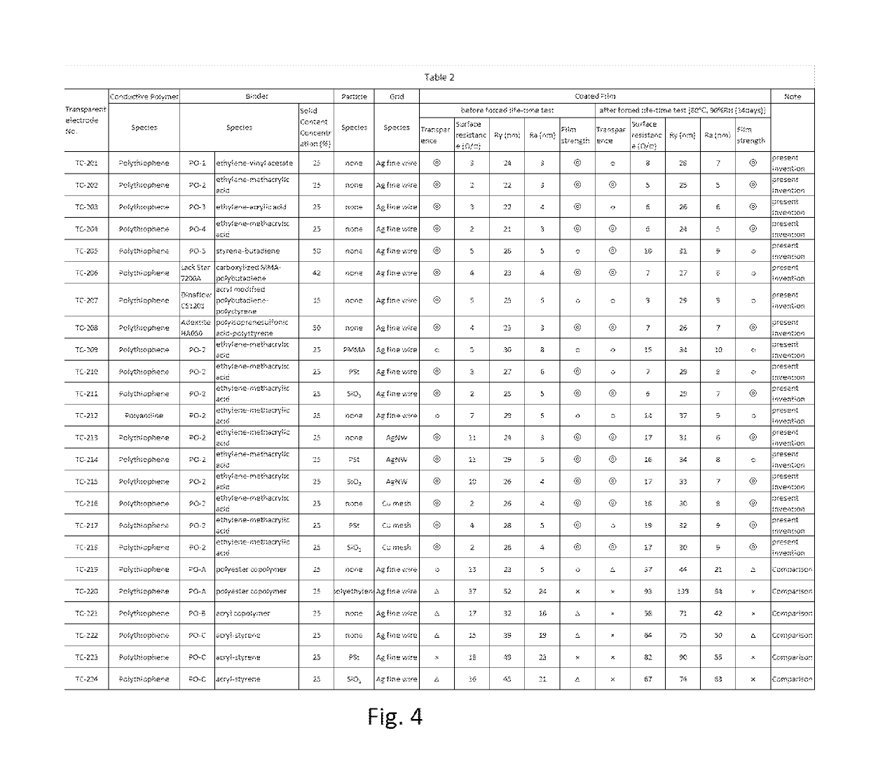

In the preparation of conductive film TC-201, polyolefin copolymer dispersion liquid of coating liquid A was exchanged as Table 2 (see also FIG. 4), and addition amount to the coating liquid A was changed to 882 mg. Conductive films TC-202˜TC-208 were produced in the same way as TC-201 except those changes.

### Production of Conductive Films TC-209˜TC-211

In the preparation of conductive film TC-201, half (441 mg) of the solid content weight of the polyolefin dispersion of the coating liquid A was changed to cross-linked PMMA fine particle (Taftic FH-S010, mean particle size 300 nm, solid content concentration 27% made by Toyobo Co.), polystyrene fine particle (5003A, mean particle size 30 nm, solid content concentration 10% made by Moritex Co.), colloidal silica (Snowtex O, mean particle size 18 nm, solid content concentration 20.6%, made by Nissan Chemical Industries Co.). Conductive films TC-209˜TC-211 were produced in the same way as TC-201 except that change.

### Production of Conductive Film TC-212

In the preparation of conductive film TC-201, PEDOT/PSS CLEVIOS PH510 of the coating liquid A was changed to polyaniline M (solid content concentration 6.0%, TA Chemical Co.) 6.3 g. Conductive film TC-212 was produced in the same way as TC-201 except that change.

### Production of Conductive Film TC-213

### Random Mesh Structure

To prepare silver nano wire dispersion liquid, silver nano wire of mean minor axis 75 nm and mean length 35 μm was produced using Adv. Mater., 2002, 14, 833˜837 for reference and using PVP K30 (molecular weight 50,000; made by IPS Co.). Then the silver nano wire was filtrated by ultrafiltration membrane and washed, thereafter, silver nano wire dispersed again in the solution to which hydroxypropyl methyl cellulose 60SH-50 (made by Shin-Etsu Chemical Co.) 25 weight % to the silver was added. Then silver nano wire dispersion liquid was prepared.

Random mesh structure was produced with silver nano wire as following.

Silver nano wire dispersion liquid was coated with bar coat method to form basis weight 0.06 g/m², then heated and dried at 110° C., for 5 minutes. And a substrate of silver nano wire was produced.

The second conductive layer was formed in the same manner as the production of the conductive film TC-202 using the same coating liquid A as TC-202 using, on the first conductive layer forming random mesh structure by silver nano wire. Then the film was cut in the size of 8×8 cm. Obtained electrode was heated with oven at 110° C., for 15 minutes. Then a conductive film TC-213 was produced.

### Production of Conduct Film TC-214, TC-215

Conduct films TC-214, TC-215 were produced in the same manner as the production of the conductive film TC-213 except using the coating liquid A, which was used in the production of the conductive film TC-210, TC-211.

### Production of Conduct Film TC-216

### Copper Mesh Substrate

Copper mesh was formed as supporting electrode on the substrate in the following method, and was patterned by metal particle elimination liquid BF, then copper mesh substrate was produced.

A catalyst ink, including palladium nano particle, JIPD-7 made by Morimura Chemicals Co. was used and self-dispersion type carbon black liquid CAB-O-JET300 made by Cabot Co. was added in it at the ratio carbon black to catalyst ink 10.0 weight %, and Surfynol 465 (made by Nissin Chemical Co.) was added to prepare conductive ink surface tension of 48 mN/m at 25° C.

The conductive ink was loaded on the ink jet printer, which has piezo type head as an ink jet printing head with pressure applying means and electric field applying means, and with nozzle diameter 25 μm, drive frequency 12 kHz, nozzle number 128, nozzle density 180 dpi (dpi means dot number in one inch, 2.54 cm). Lattice type conductive fine line of line width 10 μm, dried film thickness 0.5 μm, lien space 300 μm was formed on the substrate in the part of FIG. 1A, then dried.

Next, the substrate was immersed in high speed electroless copper plating liquid CU-5100 made by Meltex Co. at 55° C. for 10 minutes, then washed. Electroless plating was performed and supporting electrode of plate thickness 3 μm was produced.

The second conductive layer was formed in the same manner of the production of the conductive film TC-202 using the coating liquid A, on the conductive layer forming the first conductive layer with a copper mesh. The film was cut in the size of 8×8 cm. An obtained electrode was heated at 110° C. for 15 minutes, then a conductive film TC-216 was produced.

### Production of Conductive Films TC-217, TC-218

Conduct films TC-217, TC-218 were produced in the same manner as the production of the conductive film TC-213 except using the coating liquid A, which was used in the production of the conductive film TC-210, TC-211.

### Production of a Comparative Conductive Film TC-219

In the preparation of conductive film TC-201, polyolefin copolymer dispersion liquid of coating liquid A was exchanged as Table 2 (see also FIG. 4), and addition amount to the coating liquid A was changed to 882 mg. A comparative conductive film TC-219 was produced in the same way as the conductive film TC-201 except those changes.

### Production of a Comparative Conductive Film TC-220

In the preparation of conductive film TC-219, half (441 mg) of the solid content weight of the polyolefin dispersion of the coating liquid A was changed to polyethylene particle (Ceracol 39, mean particle size 13000 nm, solid content concentration 40% made by BYK Chemie Co.). A comparative conductive film TC-220 was produced in the same way as the conductive film TC-219 except that change.

### Production of Comparative Conductive Films TC-221, TC-222

In the preparation of conductive film TC-201, polyolefin copolymer dispersion liquid of coating liquid A was exchanged as Table 2 (see also FIG. 4), and addition amount to the coating liquid A was changed to 882 mg. Comparative conductive films TC-221, TC-222 were produced in the same way as the conductive film TC-201 except those changes.

### Production of Comparative Conductive Films TC-223˜TC-224

In the preparation of conductive film TC-222, half (441 mg) of the solid content weight of the polyolefin dispersion of the coating liquid A was changed to polystyrene fine particle (5003A, mean particle size 30 nm, solid content concentration 10% made by Moritex Co.), colloidal silica (Snowtex O, mean particle size 18 nm, solid content concentration 20.6%, made by Nissan Chemical Industries Co.). Conductive films TC-223˜TC-224 were produced in the same way as the conductive film TC-222 except that change.

### Evaluation of Conductive Films

Obtained conductive films having surface resistance less than 30 Ω/□ come up to the standard of the present invention. Other properties are evaluated in the same way of Example 1. The result of evaluation is shown in a Table 2 (also shown in FIG. 4).

TABLE 2

| | | Binder | | | | | |
|---|---|---|---|---|---|---|---|
| | | | | Solid | | | Coated Film |
| Transparent | Conductive | | | Content | | | before forced |
| electrode | Polymer | | | Concentration | Particle | Grid | life-time test |
| No. | Species | Species | | (%) | Species | Species | Transparence |
| TC-201 | Polythiophene | PO-1 | ethylene- | 25 | none | Ag | ⊚ |
| | | | vinyl acetate | | | fine wire | |
| TC-202 | Polythiophene | PO-2 | ethylene- | 25 | none | Ag | ⊚ |
| | | | methacrylic acid | | | fine wire | |
| TC-203 | Polythiophene | PO-3 | ethylene- | 25 | none | Ag | ⊚ |
| | | | acrylic acid | | | fine wire | |
| TC-204 | Polythiophene | PO-4 | ethylene- | 25 | none | Ag | ⊚ |
| | | | methacrylic acid | | | fine wire | |
| TC-205 | Polythiophene | PO-5 | styrene- | 50 | none | Ag | ⊚ |
| | | | butadiene | | | fine wire | |
| TC-206 | Polythiophene | Lack Star | carboxy- | 42 | none | Ag | ⊚ |
| | | 7200A | lized MMA- | | | fine wire | |
| | | | polybutadiene | | | | |
| TC-207 | Polythiophene | Dinaflow | acryl modified | 15 | none | Ag | ⊚ |
| | | C51201 | polybutadiene- | | | fine wire | |
| | | | polystyrene | | | | |
| TC-208 | Polythiophene | Adextite | polyiso- | 50 | none | Ag | ⊚ |
| | | HA050 | prenesulfonic | | | fine wire | |
| | | | acid-polystyrene | | | | |
| TC-209 | Polythiophene | PO-2 | ethylene- | 25 | PMMA | Ag | ◯ |
| | | | methacrylic acid | | | fine wire | |
| TC-210 | Polythiophene | PO-2 | ethylene- | 25 | PSt | Ag | ⊚ |
| | | | methacrylic acid | | | fine wire | |
| TC-211 | Polythiophene | PO-2 | ethylene- | 25 | SiO₂ | Ag | ⊚ |
| | | | methacrylic acid | | | fine wire | |
| TC-212 | Polyaniline | PO-2 | ethylene- | 25 | none | Ag | ◯ |
| | | | methacrylic acid | | | fine wire | |
| TC-213 | Polythiophene | PO-2 | ethylene- | 25 | none | AgNW | ⊚ |
| | | | methacrylic acid | | | | |
| TC-214 | Polythiophene | PO-2 | ethylene- | 25 | PSt | AgNW | ⊚ |
| | | | methacrylic acid | | | | |
| TC-215 | Polythiophene | PO-2 | ethylene- | 25 | SiO₂ | AgNW | ⊚ |
| | | | methacrylic acid | | | | |
| TC-216 | Polythiophene | PO-2 | ethylene- | 25 | none | Cu mesh | ⊚ |
| | | | methacrylic acid | | | | |
| TC-217 | Polythiophene | PO-2 | ethylene- | 25 | PSt | Cu mesh | ⊚ |
| | | | methacrylic acid | | | | |
| TC-218 | Polythiophene | PO-2 | ethylene- | 25 | SiO₂ | Cu mesh | ⊚ |
| | | | methacrylic acid | | | | |
| TC-219 | Polythiophene | PO-A | polyester | 25 | none | Ag | ◯ |
| | | | copolymer | | | fine wire | |
| TC-220 | Polythiophene | PO-A | polyester | 25 | polyethylene | Ag | Δ |
| | | | copolymer | | | fine wire | |
| TC-221 | Polythiophene | PO-B | acryl copolymer | 25 | none | Ag | Δ |
| | | | | | | fine wire | |
| TC-222 | Polythiophene | PO-C | acryl-styrene | 25 | none | Ag | Δ |
| | | | | | | fine wire | |
| TC-223 | Polythiophene | PO-C | acryl-styrene | 25 | PSt | Ag | X |
| | | | | | | fine wire | |
| TC-224 | Polythiophene | PO-C | acryl-styrene | 25 | SiO₂ | Ag | Δ |
| | | | | | | fine wire | |

| | Coated Film | | | | | | | | | |
|---|---|---|---|---|---|---|---|---|---|---|
| | | | | | after forced life-time test | | | | | |
| | before forced life-time test | | | | [80° C., 90% RH (14 days)] | | | | | |
| Transparent | Surface | | | | | Surface | | | | |
| electrode | resistance | Ry | Ra | Film | | resistance | Ry | Ra | Film | |
| No. | (Ω/□) | (nm) | (nm) | strength | Transparence | (Ω/□) | (nm) | (nm) | strength | Note |
| TC-201 | 3 | 24 | 3 | ⊚ | ◯ | 8 | 28 | 7 | ⊚ | present |
| | | | | | | | | | | invention |
| TC-202 | 2 | 22 | 3 | ⊚ | ⊚ | 5 | 25 | 5 | ⊚ | present |
| | | | | | | | | | | invention |
| TC-203 | 3 | 22 | 4 | ⊚ | ◯ | 6 | 26 | 6 | ⊚ | present |
| | | | | | | | | | | invention |
| TC-204 | 2 | 21 | 3 | ⊚ | ⊚ | 6 | 24 | 5 | ⊚ | present |
| | | | | | | | | | | invention |
| TC-205 | 5 | 26 | 5 | ◯ | ⊚ | 10 | 31 | 9 | ◯ | present |
| | | | | | | | | | | invention |
| TC-206 | 4 | 23 | 4 | ⊚ | ⊚ | 7 | 27 | 8 | ◯ | present |
| | | | | | | | | | | invention |
| TC-207 | 5 | 25 | 5 | ◯ | ◯ | 9 | 29 | 9 | ◯ | present |
| | | | | | | | | | | invention |
| TC-208 | 4 | 23 | 3 | ⊚ | ⊚ | 7 | 26 | 7 | ⊚ | present |
| | | | | | | | | | | invention |
| TC-209 | 5 | 30 | 8 | ◯ | ◯ | 15 | 34 | 10 | ◯ | present |
| | | | | | | | | | | invention |
| TC-210 | 3 | 27 | 6 | ⊚ | ◯ | 7 | 29 | 8 | ◯ | present |
| | | | | | | | | | | invention |
| TC-211 | 2 | 25 | 5 | ⊚ | ⊚ | 6 | 29 | 7 | ⊚ | present |
| | | | | | | | | | | invention |
| TC-212 | 7 | 29 | 5 | ◯ | ◯ | 14 | 37 | 9 | ◯ | present |
| | | | | | | | | | | invention |
| TC-213 | 11 | 24 | 3 | ⊚ | ⊚ | 17 | 31 | 6 | ⊚ | present |
| | | | | | | | | | | invention |
| TC-214 | 12 | 25 | 5 | ⊚ | ⊚ | 16 | 34 | 8 | ◯ | present |
| | | | | | | | | | | invention |
| TC-215 | 10 | 26 | 4 | ⊚ | ⊚ | 17 | 33 | 7 | ⊚ | present |
| | | | | | | | | | | invention |
| TC-216 | 2 | 26 | 4 | ⊚ | ⊚ | 18 | 30 | 8 | ⊚ | present |
| | | | | | | | | | | invention |
| TC-217 | 4 | 28 | 5 | ⊚ | ◯ | 19 | 32 | 9 | ⊚ | present |
| | | | | | | | | | | invention |
| TC-218 | 2 | 26 | 4 | ⊚ | ⊚ | 17 | 30 | 9 | ⊚ | present |
| | | | | | | | | | | invention |
| TC-219 | 13 | 23 | 5 | ◯ | Δ | 37 | 44 | 21 | Δ | Comparison |
| TC-220 | 37 | 52 | 24 | X | X | 95 | 139 | 84 | X | Comparison |
| TC-221 | 17 | 32 | 16 | Δ | X | 56 | 71 | 42 | X | Comparison |
| TC-222 | 15 | 39 | 19 | Δ | X | 64 | 75 | 50 | Δ | Comparison |
| TC-223 | 16 | 49 | 23 | X | X | 82 | 90 | 55 | X | Comparison |
| TC-224 | 16 | 45 | 21 | Δ | X | 67 | 74 | 63 | X | Comparison |

The Table 2 shows that the conductive film TC-201˜218 of the present invention have preferable smoothness, conductivity, light transmittance and film strength to the comparative conductive film TC-219˜224 and that degradation of smoothness, conductivity, light transmittance and film strength of the present invention under hot and humid environment is small and that the present invention has better stability.

### Example 3

### Production of Organic EL Element

The conductive films produced in example 2 were washed with ultrapure water, thereafter films were cut in the size of 30 mm×30 mm, in which one square tile type pattern 20 mm×20 mm should be situated in the center. Each organic EL element using such an anode electrode was produced by following process. A hole transfer layer and other layers were formed by deposition. Each organic EL element OEL-301˜OEL-324 was produced using the conductive film TC-201˜TC-224.

Element material of each layer of necessary amount for producing devices was filled in each melting pot for deposition in a commercially available vacuum deposition equipment. The used melting pots for deposition were made of molybdenum or tungsten for heat resistance.

At first, organic EL layer comprising a hole transfer layer, an organic light emission layer, a hole blocking layer, an electron transfer layer was formed in order.

### Production of a Hole Transfer Layer

Pressure was reduced to the degree of vacuum 1×10⁻⁴ Pa, thereafter said melting pot for deposition filled with Compound 1 was heated electrically. Deposition was performed at deposition rate 0.1 nm/sec and a hole transfer layer of thickness 30 nm was formed.

### Production of an Organic Light Emission Layer

Next, each light emission layer was formed in the following manner.

Compound 2 of weight 13.0 weight %, Compound 3 of 3.7 weight %, Compound 5 of 83.3 weight % should be deposited on the formed hole transfer layer, so Compound 2, Compound 3 and Compound 5 were deposited together at deposition rate 0.1 nm in the same region of the hole transfer layer. An organic light emission layer of green-red phosphorescent emission, which has the maximum emission wave length 622 nm and thickness 10 nm, was formed.

Next, Compound 4 of 10.0 weight % and Compound 5 of 90 weight % should be deposited, so Compound 4 and Compound 5 were deposited together at deposition rate 0.1 nm in the same region of the green-red phosphorescent emission layer. An organic light emission layer of blue phosphorescent emission, which has the maximum emission wave length 471 nm and thickness 15 nm, was formed.

### Production of a Hole Blocking Layer

Further, Compound 6 was deposited in the same region of the formed organic light emission layer. Then a hole blocking layer of 5 nm film thickness was formed.

### Production of an Electron Transfer Layer

Further, CsF, which should have 10% thickness of the film of Compound 6, and Compound 6 were deposited together in the same region of the formed hole blocking layer. Then an electron transfer layer of 45 nm film thickness was formed.

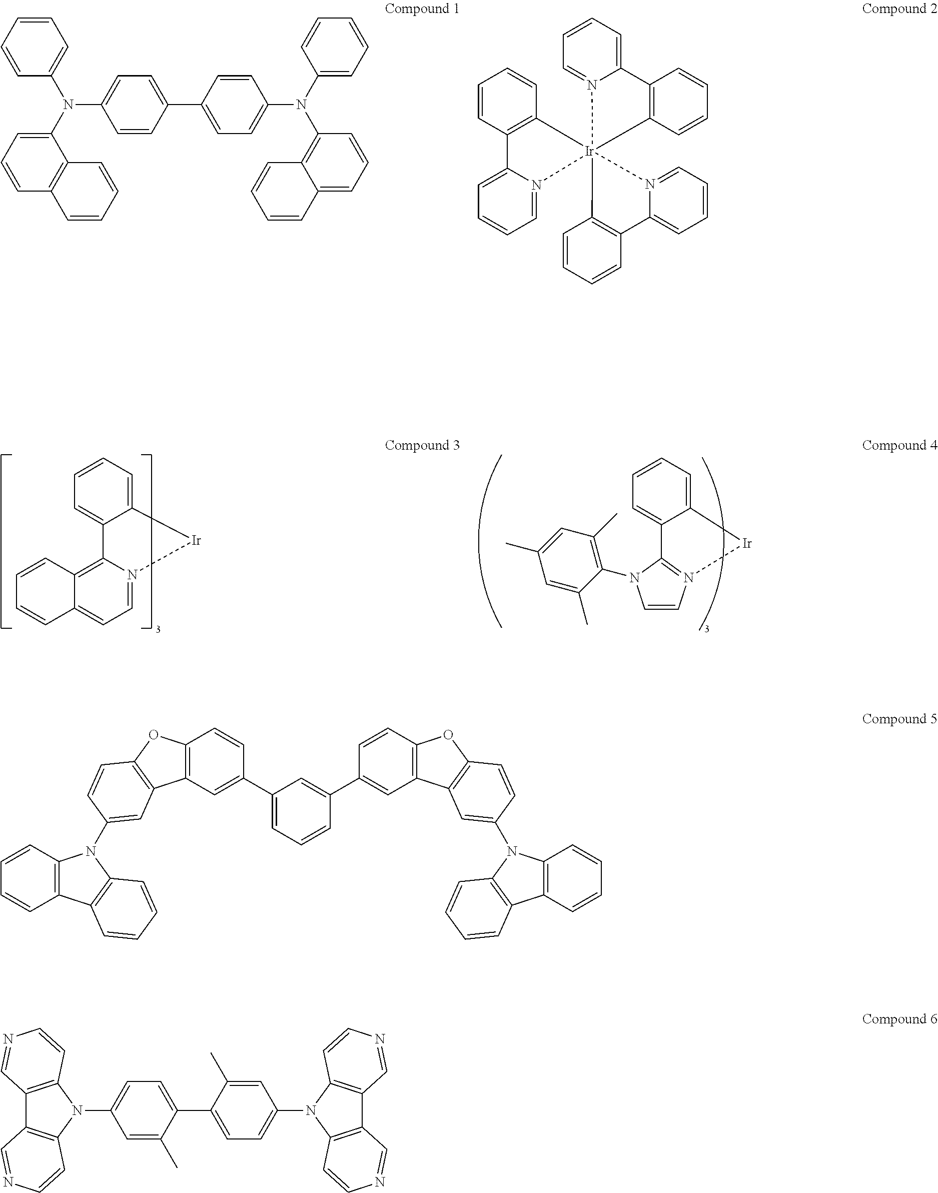

### Production of a Cathode Electrode

Conductive film was used as cathode, terminal for an external extraction of cathode electrode was used and Al as anode forming material of 15 mm×15 mm on the formed electron transfer layer was deposited with mask to produce 100 nm thick cathode under vacuum condition 5×10⁻⁴ Pa.

Further, an adhesive agent was applied around the cathode except an edge to form terminal for external extraction of anode and cathode. Polyethylene telephthalate used as substrate, and Al₂O₃ of 300 nm was deposited, then obtained flexible sealing materials were pasted together, then the adhesion agent was cured by heat treatment to form sealing film, thereby organic EL elements which has the light emission area of 15 mm×15 mm, were produced.

### Evaluation of Organic EL Element

Obtained organic EL elements were evaluated about irregularity of brightness and life-time as following.

### Homogeneity of Light Emission

Homogeneity of light emission was measured with Source Major Unit 2400 made by Keithley Co. An organic EL element was charged with DC and light was emitted. 1000 cd/m2 was emitted by organic EL element OEL-201˜OEL 224, which irregularity (before forced life-time test) of each brightness of light emission were observed with a microscope of 50 magnification. Further, organic EL element OEL-201˜OEL-218 were in the oven of 60% RH, 80° C. for 2 hours, then in the condition 55±3% RH, 23±3° C. for more than 1 hour, thereafter homogeneity of light emission were observed in the same manner. (after forced life-time test)

⊚: complete homogeneity of light emission, nothing to criticize.

◯: almost homogeneity of light emission, no problem.

Δ: partially irregularity of light emission was observed, in allowable range.

×: irregularity of light emission was observed on the whole surface, not allowable.

Evaluation Standard: ⊚, ◯ of evaluated samples after forced life-time test came to the standard of the present invention.

### Life-Time

The time of becoming half brightness was observed after obtained organic EL element emitting 5000 cd/m² as initial brightness and the emission continued until the brightness became half of 5000 cd/m². An organic EL element with ITO anode electrode was produced in the similar process of upper organic EL element. A time ratio to the organic EL element with ITO anode electrode were calculated and evaluated with the following standards after forced life-time test. The ratio is preferably more than 100%, more preferably more than 150%.

⊚: more than 150%

◯: more than 100%, and less than 150%

Δ: more than 80%, and less than 100%

×: less than 80%

Evaluation Standard: ⊚, ◯ of evaluated samples after forced life-time test came to the standard of the present invention.

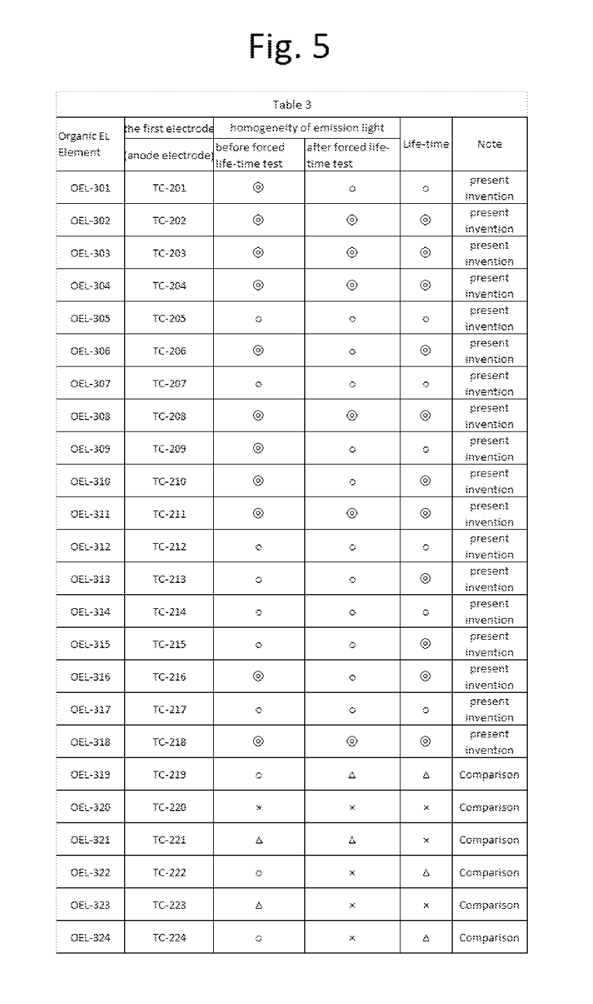

The result of the evaluation is shown in the Table 3 (also shown in FIG. 5). “Present Invention” in the column “Note” means an example of the present invention. “Comparison” means a comparative example.

TABLE 3

| | the first | | | | |
|---|---|---|---|---|---|
| | elec- | homogeneity of emission light | | | |
| | trode | before | after | | |
| Organic | (anode | forced | forced | | |
| EL | elec- | life- | life- | Life- | |
| Element | trode) | time test | time test | time | Note |
| OEL-301 | TC-201 | ⊚ | ◯ | ◯ | present |
| | | | | | invention |
| OEL-302 | TC-202 | ⊚ | ⊚ | ⊚ | present |
| | | | | | invention |
| OEL-303 | TC-203 | ⊚ | ⊚ | ⊚ | present |
| | | | | | invention |
| OEL-304 | TC-204 | ⊚ | ⊚ | ⊚ | present |
| | | | | | invention |
| OEL-305 | TC-205 | ◯ | ◯ | ◯ | present |
| | | | | | invention |
| OEL-306 | TC-206 | ⊚ | ◯ | ⊚ | present |
| | | | | | invention |
| OEL-307 | TC-207 | ◯ | ◯ | ◯ | present |
| | | | | | invention |
| OEL-308 | TC-208 | ⊚ | ⊚ | ⊚ | present |
| | | | | | invention |
| OEL-309 | TC-209 | ⊚ | ◯ | ◯ | present |
| | | | | | invention |
| OEL-310 | TC-210 | ⊚ | ◯ | ⊚ | present |
| | | | | | invention |
| OEL-311 | TC-211 | ⊚ | ⊚ | ⊚ | present |
| | | | | | invention |
| OEL-312 | TC-212 | ◯ | ◯ | ◯ | present |
| | | | | | invention |
| OEL-313 | TC-213 | ◯ | ◯ | ⊚ | present |
| | | | | | invention |
| OEL-314 | TC-214 | ◯ | ◯ | ◯ | present |
| | | | | | invention |
| OEL-315 | TC-215 | ◯ | ◯ | ⊚ | present |
| | | | | | invention |
| OEL-316 | TC-216 | ⊚ | ◯ | ⊚ | present |
| | | | | | invention |
| OEL-317 | TC-217 | ◯ | ◯ | ◯ | present |
| | | | | | invention |
| OEL-318 | TC-218 | ⊚ | ⊚ | ⊚ | present |
| | | | | | invention |
| OEL-319 | TC-219 | ◯ | Δ | Δ | Comparison |
| OEL-320 | TC-220 | X | X | X | Comparison |
| OEL-321 | TC-221 | Δ | Δ | X | Comparison |
| OEL-322 | TC-222 | ◯ | X | Δ | Comparison |
| OEL-323 | TC-223 | Δ | X | X | Comparison |
| OEL-324 | TC-224 | ◯ | X | Δ | Comparison |

Table 3 shows that organic EL elements OEL-319˜OEL-324 of comparative examples dropped very much in the homogeneity of emission light after a forced life-time test of 60% RH, 80° C. for 2 hours and that organic EL elements OEL-301˜OEL-318 of the present invention has the stable homogeneity of light emission and good durability even after the forced life-time test.

### Example 4

### Production of Touch Panel

A touch panel 101 shown in the FIG. 2 was assembled in the following manner using said conductive film TC-201˜TC-224.

### Assembling Method of Touch Panel

As shown in FIG. 2, a touch panel 101 is comprised of a lower electrode 110, upper electrode 120 and heat curable type dot spacer 130 between the electrodes 110 and 120. The lower electrode 110 is a glass ITO (layer was formed by spattering) for touch panel, and the electrode 110 is comprised of glass for touch panel 111 and transparent conductive film 112 on said glass for touch panel 111. The upper electrode 120 has a conductive film of said examples (conductive film TC-201˜TC-218 of the present invention and comparative conductive film TC-219˜224), and the electrode 120 is comprised of transparent substrate 121 and transparent conductive layer 122. And conductive transparent layer 112 of lower electrode 110 lies face to face to the conductive transparent layer 122 of upper electrode 120 and heat curing type dot spacer 130 lies between the electrodes, which has 7 μm space between them to form panel. Thereafter touch panel 101 was assembled.

An appropriate picture was laid under the touch panel 101 assembled in these ways, visibility test was performed if the picture through the panel was seen distorted or not, when picture was observed from slanted direction 45° C. Distortion of the picture was not observed on the conductive films TC-201˜TC-218 of the present invention, but distortion of the picture was observed on the comparative conductive films TC-219˜TC-224.

1. A conductive film comprising:
a substrate and
a conductive organic compound layer formed on said substrate,
wherein said organic compound layer includes:
cationic π conjugated conductive polymer,
conductive polymer compound having poly-anion, and
polyolefin copolymer.

2. The conductive film according to claim 1, wherein said polyolefin copolymer is a copolymer of ethylene and (meth)acrylic acid.

3. The conductive film according to claim 1, wherein said organic compound layer includes fine particles.

4. The conductive film according to claim 1, wherein on the said substrate, formed
a first conductive layer composed of patterned metal material and
a second conductive layer composed of said organic compound layer connected electrically to said first conductive layer.

5. An organic electroluminescent element, comprising the conductive film according to claim 1 as an electrode.

6. The conductive film according to claim 2 wherein said organic compound layer includes fine particles.
